(19) United States
(12) Patent Application Publication
(10) Pub. No.: US 2017/0278762 A1
(43) Pub. Date: Sep. 28, 2017

(54) Redirecting solder material to visually inspectable package surface

(71) Applicant: Infineon Technologies AG, Neubiberg (DE)

(72) Inventors: Angela KESSLER, Sinzing (DE); Oliver HAEBERLEN, Magdalen (AT); Matteo-Alessandro KUTSCHAK, Ludmannsdorf (AT); Ralf OTREMBA, Kaufbeuren (DE); Petteri PALM, Regensburg (DE); Boris PLIKAT, Tegernheim (DE); Thorsten SCHARF, Regensburg (DE); Klaus SCHIESS, Allensbach (DE); Fabian SCHNOY, Tegernheim (DE); Erich SYRI, Regensburg (DE)

(21) Appl. No.: 15/468,045

(22) Filed: Mar. 23, 2017

(30) Foreign Application Priority Data
Mar. 24, 2016 (DE) 10 2016 105 581.6

(51) Int. Cl. H01L 21/66; H01L 23/498; G01N 21/84; H01L 23/31

(52) U.S. Cl. CPC H01L 22/32; H01L 23/3114; H01L 23/49838; H01L 23/49816; H01L 23/49861; H01L 23/49805; H01L 23/49827; H01L 23/49866; G01N 21/84; H01L 2924/01047; H01L 2924/01079; H01L 2924/01028; H01L 2924/01046; H01L 2924/01078; H01L 2924/052; H01L 2924/0105; H01L 2924/10253; H01L 2924/10272; H01L 2924/1033; H01L 2924/10271; G01N 2201/12

(57) ABSTRACT

A package comprising an electronic chip, a laminate type encapsulant in and/or on which the electronic chip is mounted, a solderable electric contact on a solder surface of the package, and a solder flow path on and/or in the package which is configured so that, upon soldering the electric contact with a mounting base, part of solder material flows along the solder flow path towards a surface of the package at which the solder material is optically inspectable after completion of the solder connection between the mounting base and the electric contact.

### BACKGROUND OF THE INVENTION

Field of the Invention

The present invention relates to packages, an arrangement, a method of inspecting a solder connection, and a method of use.

Description of the Related Art

Packages may be denoted as encapsulated electronic chips with electrical connects extending out of the encapsulant and being mountable to an electronic periphery, for instance on a printed circuit board. The package may be connected to the printed circuit board (PCB) by soldering. For this purpose, solder bumps or the like may be provided at an exterior surface of the package which are to be connected with solder pads of the PCB.

For certain applications, it is desired to inspect the quality of the solder connection. However, when a package is mounted on a mounting base such as a PCB by soldering, the solder material may be visually hidden in view of the spatially close connection between PCB and package. Consequently, a cumbersome X-ray inspection is necessary to inspect such a visually hidden solder connection.

### SUMMARY OF THE INVENTION

There may be a need for a package allowing for a simple and reliable inspection of a solder connection.

According to an exemplary embodiment, a package is provided which comprises an electronic chip, a laminate type encapsulant in and/or on which the electronic chip is mounted, a solderable electric contact (such as a pad) on a solder surface of the package, and a solder flow path on and/or in the package which is configured so that, upon soldering the electric contact with a mounting base, part of solder material flows along the solder flow path towards a surface of the package at which the solder material is optically inspectable after completion of the solder connection between the mounting base and the electric contact.

According to another exemplary embodiment, a package is provided which comprises an electronic chip, an encapsulant (in particular and preferably a laminate-type encapsulant, or a mold-type encapsulant) encapsulating at least part of the electronic chip, a solderable electric contact on a solder surface of the package, and a solder-wettable structure in contact with the encapsulant and arranged so that, upon soldering the electric contact, part of solder material flows onto the solder-wettable structure, wherein at least a portion of the solder-wettable structure is located at a surface of the package which is visually inspectable after completion of the solder connection of the package on a mounting base.

According to still another exemplary embodiment, an arrangement is provided which comprises a package having the above mentioned features, and an optical inspection device arranged for optically inspecting solder material on the optically inspectable surface of the package.

According to yet another exemplary embodiment, a method of inspecting a solder connection between a package and a mounting base is provided, wherein the method comprises providing the package with an electronic chip mounted on and/or in a laminate type encapsulant and with a solderable electric contact on a solder surface of the package at which the package is to be connected with the mounting base by soldering, forming a solder connection between the solderable electric contact on the solder surface of the package and the mounting base in such a way that part of solder material flows from the solder surface to an optically accessible surface of the package connected with the mounting base, and optically inspecting the flown solder material on the optically accessible surface of the package.

According to still another exemplary embodiment, solder material which has flown, during soldering, from a visually non-inspectable surface of an embedded package to a visually inspectable surface of the package is used for optically inspecting the solder material.

According to an exemplary embodiment of the invention, a chip package comprising an encapsulant at which a solderable electric contact is exposed for establishing a connection with a mounting base is equipped with a provision allowing to monitor solder material after the soldering even when the actual solder connection between package and mounting base is no longer visually inspectable. Such a loss of visual or optical inspectability can be the consequence of a very small remaining gap or even direct physical contact between package and mounting base being electrically and mechanically connected by the solder. When being connected by soldering, the solder surface of the package and a counter surface of the mounting base may face each other with the solder material in between. In conventional approaches, cumbersome X-ray inspection has been used to obtain information with regard to such a hidden solder connection. In contrast to this, an exemplary embodiment of the invention allows to perform such an inspection with simple optical measures (for instance an optical inspection device such as a camera or a visual inspection by a human operator) by triggering a flow of solder material from the solder surface to another surface region of the package which remains visually accessible even after establishing the solder connection between package and mounting base. According to an exemplary embodiment, this can be accomplished by a solder flow path which can be embodied as a defined trajectory along which a material is exposed which is properly wettable by solder material. Since not each and every material is capable of allowing solder to wet the material, it is possible to precisely define a solder flow path by a path along which wettable material, surrounded by non-wettable material, is provided. This allows to redirect part of the solder material to flow, when liquefied during a solder procedure, selectively along the solder flow path to a surface at which visual inspection is desired. According to an exemplary embodiment, the described phenomenon is hence used to precisely define and predict a flow path of the solder so that sufficient accumulation of solder material can be promoted at a desired location at which visual inspection is possible or is carried out. This renders cumbersome X-ray investigations dispensable. Advantages connected with the implementation of a solder flow path are particularly pronounced with laminate type encapsulants, since corresponding packages are usually plate-shaped flat structures in which the loss of a visually inspectable surface area upon soldering the package to a plate-shaped mounting base is particularly pronounced. Consequently, exemplary embodiments allow to realize a highly efficient lead tip inspection.

### DESCRIPTION OF FURTHER EXEMPLARY EMBODIMENTS

In the following, further exemplary embodiments of the packages, the arrangement, the method of inspecting a solder connection, and the method of use will be explained.

In the context of the present application, the term “package” may particularly denote at least one at least partially encapsulated or surface mounted electronic chip with at least one external electric contact (also denoted as pad in this description). The electronic chip may be a semiconductor chip having at least one integrated circuit element (such as a diode or a transistor) in a surface portion thereof. The electronic chip may be a naked die or may be already packaged or encapsulated. Such an electronic chip may be embedded in the interior of the encapsulant, or may be surface mounted thereon.

In the context of the present application, the term “laminate-type encapsulant” may particularly denote a substantially electrically insulating and preferably thermally conductive material forming a support for or at least partially surrounding (preferably hermetically surrounding) a semiconductor chip or the like in order to provide mechanical protection, electrical installation, and optionally a contribution to heat removal during operation. Such a laminate-type encapsulant can be provided of several layers connected to one another by applying a pressure at an elevated temperature. Thereby, the layers of which the laminate-type encapsulant is composed are interconnected to one another so that the laminate-type encapsulant is formed. For instance, a laminate-type encapsulant may comprise resin, in particular in combination with fibers. A laminate-type encapsulant may be made for instance of FR4 or prepreg.

In the context of the present application, the term “solderable electric contact” may particularly denote electrically conductive material such as tin which forms an integral mechanically robust and electrically conductive contact with a solder pad of a mounting base, preferably with a solder depot (such as a tin bead) in between. Such a solderable electric contact may be shaped as a bump or maybe a flat layer or layer structure.

In the context of the present application, the term “solder flow path” may particularly denote a defined trajectory of solder-wettable material at least partially on a surface of (but optionally also partially within) the package (in particular on and/or in the encapsulant) along which solder material flows triggered by the establishment of a solder connection between the electric contact of the package and a solder pad of the mounting base. In contrast to this, material adjacent to the solder flow path may lack wettability by a solder material, so that the solder material can be safely prevented to propagate along undesired paths. Correspondingly, “wetting” or “wettability” may denote the ability of a liquid phase to maintain contact with a solid surface, resulting from intermolecular interactions, etc., when the two are brought together. The degree of wetting or wettability may be determined or influenced by a force balance between adhesive and cohesive forces. A solder-wettable structure has the capability of being wetted by molten or liquid solder material.

In the context of the present application, the term “optically inspectable” or “visually inspectable” may particularly denote the suitability of a surface of the package to be inspected or monitored by non-invasive electromagnetic radiation (such as visual light, infrared radiation, ultraviolet radiation). Such electromagnetic radiation may propagate along a continuous line of sight from the inspected surface to an inspecting entity (such as an optical inspection device or a human operator). Alternatively, such electromagnetic radiation may propagate along an angled path by implementing one or more optical elements (such as a mirror or a prism). Hence, inspection may also be accomplished using one or more optical elements between the inspected surface and the inspecting entity. In contrast to this, “optically non-inspectable” or “visually non-inspectable” are surfaces of the packages lacking a continuous line of sight from an exterior position of the package or arrangement.

In an embodiment, the solder flow path is configured so that flow of solder material onto an optically inspectable surface of the package wets such an optically inspectable surface at least along an optically inspectable distance (for instance the height of a meniscus of solder material) of 30 μm, in particular at least along an optically inspectable distance of 100 μm. Investigations have shown that oblique inspection is sufficiently accurately possible with an optically inspectable distance of at least 30 μm. Investigations have shown as well that highly accurate inspection is possible with an optically inspectable distance of at least 100 μm.

In an embodiment, the solder flow path is defined by a solder-wettable structure on the optically inspectable surface on the encapsulant. The solder-wettable structure can be surrounded by material being non-wettable by solder material so that the spatial regions in which the solder material flows from an actual solder position to an optically inspectable surface region of the package can be precisely defined.

In an embodiment, the solder flow path is defined by a surface plating with solder-wettable material. Plating can be denoted as a surface covering in which an electrically conductive material such as a metal is deposited on a surface. By plating a base, an electrically conductive structure with a thickness in a range between 0.1 μm and 200 μm, in particular in a range between 20 μm and 100 μm, may be formed. For instance, a thickness of a copper base may be in a range between 10 μm and 200 μm. The solder-wettable surface can however be much thinner, for instance in a range between 0.1 μm and 10 μm. One or more of several plating methods may be implemented. For instance, a solid surface may be covered with a metal sheet, and then heat and pressure may be applied to fuse them. Other plating techniques which may be implemented include vapor deposition and sputter deposition. In the described embodiment, plating can be accomplished for improving wettability by solder material.

In an embodiment, the solder flow path comprises a cavity configured so that solder material flows into the cavity upon soldering. When providing the solder flow path with a certain curvature (for instance a concave cavity, for example forming part of a plated through hole), the wettable surface can be increased, thereby further promoting wettability by solder material.

In an embodiment, the solder flow path is defined at least partially by a surface portion of a chip carrier (such as a leadframe) on which the electronic chip is mounted. In particular, a portion of a leadframe may serve as a soldering pad. A leadframe can be in particular made of copper material which has proper wetting properties for solder materials such as created by a tin plating. When for example a side or lateral surface of a substantially plate-shaped leadframe is exposed, solder material may reflow (in particular may climb) from the solderable electric contact of the package to an exposed lateral surface of the leadframe or other chip carrier and may therefore define at least part of the solder flow path. The solder material may then be inspected by inspecting coverage of a lateral (for instance vertical or slanted) side surface of the chip carrier after soldering. This has the advantage that no specific provision (apart from the provision of a chip carrier, which is anyway present in many package applications) needs to be taken for defining the solder flow path.

In an embodiment, the solder flow path is located at least partially on a sidewall of the package. This has the advantage that the solder flow path extending from a bottom of the package to a sidewall of the package may be kept very short and hence does not significantly influence the design of the package. Furthermore, such a short solder flow path allows to obtain a relatively large amount of the material at the visually inspected end portion of the solder flow path.

In an embodiment, the solder flow path is at least partially defined by a portion of a vertical through-connection (such as a through hole with plated sidewall or a completely filled through hole) exposed on a side surface of the package. For instance, a pre-form of multiple packages manufactured in a batch procedure may be singularized at such a vertical through connection so that the separated portions of the vertical through connections are arranged each at a lateral side wall of the singularized packages and may form at least part of the solder flow path.

In an embodiment, the solder flow path is located at least partially on a top surface of the package. Since packages are usually flat and plate-shaped when implementing the architecture of a laminate-type encapsulant, formation of the solder flow path or at least the end portion thereof at the top main surface of the package ensures proper optical inspectability of a large flat surface area there. Furthermore, in such an embodiment, another part of the solder flow path may extend vertically through the encapsulant and may end at the top surface, which again ensures a very short solder flow path and hence a reliable and fast inspection of the solder material involved in the establishment of the solder connection between package and mounting base.

In an embodiment, the solder flow path is at least partially defined by a hole in the package. Such a hole may be a through hole or a blind hole. More specifically, the solder flow path may be at least partially defined by a through-hole, in particular a plated through-hole, extending through the package. Wettability of walls of such a hole may thereby be promoted not only by the material of the sidewall but also by a capillary effect within a tiny hole.

In an embodiment, the solder flow path is continuously connected with the solderable electric contact by solderable material. In other words, an uninterrupted trajectory of solder wettable material may guide from the soldered electric contact to a desired inspection position of the package. This reliably ensures that a sufficient amount of solder material actually reflows up to the visually accessible position.

In another embodiment, the solder flow path and the solderable electric contact are separated from one another by a non-wettable gap (for instance formed by material of the encapsulant) which is sufficiently narrow to allow solder material to bridge the gap upon soldering. When such a gap is arranged sufficiently narrow, the flowing solder material may traverse the gap, so that the design freedom of configuring the solder flow path may be further increased. Furthermore, this allows to electrically insulate the electric contact from the optically inspected portion of a solder-wettable structure.

In an embodiment, at least part of the solder flow path is defined by a wettable structure with a free edge configured so that solder material flows around the edge towards the optically inspectable surface upon soldering. Adhesive surface forces may promote such a motion of solder material around the corner. This may allow for a very simple and precise detection of the part of solder material which has flown around the corner of the edge.

In an embodiment, the solderable electric contact has a surface area of less than 1 mm², in particular of less than 0.25 mm², more particularly of less than 0.1 mm². Even with such a small dimension of the electric contacts and a high density of the electric contacts per surface area, reliable optical inspection of solder material at one or more positions of a package may be ensured by the concept of forcing defined flow of solder material away from a solder position to an optically accessible surface portion of the package along a highly wettable and therefore energetically favoured path.

In an embodiment, the solder flow path is defined by material selected from the group consisting of silver, gold, nickel, palladium, platinum, nickel-phosphor (NiP), organic surface protection (OSP), and tin. However, other solder-wettable materials and/or combinations of the mentioned and/or other materials and alloys may be implemented.

In an embodiment, the electronic chip is a semiconductor chip, in particular one of the group consisting of an electronic chip manufactured in silicon carbide technology, an electronic chip manufactured in gallium nitride technology, an electronic chip manufactured in silicon germanium technology (for instance for radar chip technology), and an electronic chip manufactured in silicon technology. Thus, the concept of implementing a solder flow path for simplifying visual inspection of soldering is applicable to very different semiconductor technologies.

In an embodiment, the package is configured as embedding package. In other words, the electronic components may be embedded in an interior of the package, in particular may be at least partially covered by material of a laminate-type encapsulant so as to be mechanically protected and electrically connected as well as embedded in an interior of the package. In such a package architecture, inspection of solder reliability is of utmost importance and can be rendered difficult by the mounting of a plate-shaped embedded package on a plate-shaped mounting base.

In an embodiment, the arrangement further comprises the mounting base having a solder contact (in particular a plurality of solder contacts) which is connected to the electric contact at the solder surface of the package by soldering. Such a mounting base made in particular be a printed circuit board (PCB). It may however also be a cooling body, etc. The one or more solderable electric contacts of the package may be aligned with regard to the one or more solder contacts of the mounting base. For establishing the solder connection between mounting base and package, the one or more solderable electric contacts may be brought in contact with the one or more solder contacts (in particular with solder paste or the like in between) and may be made subject to heating (for instance in a solder oven). As a result, the solder connection is established and part of the solderable material (i.e. from the one or more solderable electric contacts and/or of the one or more solder contacts and/or of solder paste or any other solder depot) is configured to flow along the solder-wettable flow path up to the inspectable surface of the package. As a result of this procedure, the arrangement may further comprise solder material on the optically inspectable surface of the package at the end of the solder procedure.

In an embodiment, the solder flow path is formed at least partially by singularizing a pre-form of multiple packages into individual packages, in particular by singularizing along a vertical through-connection. In other words, at least part of the solder flow path may be exposed upon singularization along one or more dicing lines. Efficiently, one physical structure of solder-wettable material may be thereby divided into solder flow path portions of two (or more) adjacent packages upon singularization, i.e. upon cutting along a dicing line. Hence, the solder flow path may be formed in a pre-form of multiple packages before singularizing the pre-form into multiple individual packages.

In an embodiment, the solder flow path is at least partially formed by a mechanical processing such as drilling, milling, and/or routing. Such mechanical procedures are highly efficient in separating electrically conductive structures such as copper which may serve as a basis for forming the solder flow path or part thereof. However, alternatively, also laser processing may be used for this purpose.

In an embodiment, forming the solder flow path is performed by removing material of a pre-form of multiple packages before singularization, in particular by forming the solder flow path for multiple packages simultaneously by forming a single recess in the pre-form. This allows to manufacture and in particular to expose the solder flow path with low effort, in particular for two, three or four packages at the same time.

In an embodiment, the encapsulant of the package comprises a laminate (rather than a mold compound formed by compression molding or transfer molding), in particular a printed circuit board laminate. Such a laminate structure may particularly denote an integral flat member formed by electrically insulating structures which may be connected to one another by applying a pressing force. The connection by pressing may be optionally accompanied by the supply of thermal energy. Lamination may hence be denoted as the technique of manufacturing a composite material from multiple interconnected layers. A laminate can be permanently assembled by heat and/or pressure and/or welding and/or adhesives.

In an embodiment, the one or more electronic chips of a package is a/are power semiconductor chip(s). In particular for power semiconductor chips, electric reliability and heat removal capability are important issues which can be met with the described manufacturing procedure. Possible integrated circuit elements which can be monolithically integrated in such a semiconductor power chip are field effect transistors (such as insulated gate bipolar transistors or metal oxide semiconductor field effect transistors) diodes, etc. With such constituents, it is possible to provide packages for automotive applications, high-frequency applications, etc. Examples for electric circuits which can be constituted by such and other power semiconductor circuits and packages are half-bridges, full bridges, etc.

As substrate or wafer for the semiconductor chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 illustrates a cross-section of an arrangement comprising a package on a mounting base as well as an optical inspection device according to an exemplary embodiment.

FIG. 2 illustrates a cross-sectional view of a package according to an exemplary embodiment.

FIG. 3 to FIG. 12 illustrate structures obtained during carrying out a method of manufacturing a package according to an exemplary embodiment.

FIG. 13 illustrates a cross-sectional view of a package according to an exemplary embodiment.

FIG. 14 illustrates a cross-sectional view of a package according to another exemplary embodiment.

FIG. 15 illustrates a cross-sectional view of a package according to still another exemplary embodiment.

FIG. 16 illustrates a cross-sectional view of a detail of a soldered package according to an exemplary embodiment.

FIG. 17 illustrates a cross-sectional view of a package according to yet another exemplary embodiment.

FIG. 18 illustrates a three-dimensional view of a package according to an exemplary embodiment before soldering.

FIG. 19 illustrates a three-dimensional view of a package according to an exemplary embodiment partially with and partially without solder connection.

FIG. 20 illustrates a three-dimensional view of a package according to an exemplary embodiment with solder connection.

FIG. 21 illustrates a plan view of a metallic sheet with drilled through holes used as a basis for packages according to an exemplary embodiment.

FIG. 22 illustrates a plan view of a pre-form of multiple packages after singularization.

FIG. 23 illustrates a three-dimensional view of a detail of a pad embedded in an encapsulant and being provided with a through hole.

FIG. 24 illustrates a plan view of a portion of the structure according to FIG. 22 before singularization without offset.

FIG. 25 illustrates a plan view of a portion of the structure according to FIG. 22 before singularization with offset.

FIG. 26 illustrates a plan view of a pre-form of multiple packages before singularization used as a basis for packages according to an exemplary embodiment.

FIG. 27 illustrates a plan view of the pre-form of multiple packages after singularization.

FIG. 28 illustrates a three-dimensional view of a detail of a pad embedded in and supported by an encapsulant and being provided with a through hole.

FIG. 29 illustrates a plan view of a portion of the structure according to FIG. 27 before singularization without offset.

FIG. 30 illustrates a plan view of a portion of the structure according to FIG. 27 before singularization with offset.

FIG. 31 illustrates a plan view of a pre-form of multiple packages with routed “+”-shaped slots used as a basis for packages 100 according to an exemplary embodiment.

FIG. 32 illustrates a corresponding plan view of the pre-form of multiple packages after singularization.

FIG. 33 illustrates a three-dimensional view of a detail of a pad embedded in encapsulant and being provided with a routed slot in a corner.

FIG. 34 illustrates a plan view of a pre-form of multiple packages with routed and substantially rectangular-shaped slots used as a basis for packages 100 according to an exemplary embodiment.

FIG. 35 illustrates a corresponding plan view of the pre-form of multiple packages after separation into distinct sections.

FIG. 36 illustrates a three-dimensional view of a detail of a pad embedded in encapsulant and being provided with a routed slot in a corner.

FIG. 37 illustrates a plan view of a pre-form of multiple packages before singularization according to an exemplary embodiment.

FIG. 38 illustrates a detail of FIG. 37.

FIG. 39 illustrates a cross-sectional view of a portion of a package according to FIG. 37 solder connected to a mounting base according to an exemplary embodiment.

FIG. 40 illustrates a plan view of a pre-form of multiple packages according to an exemplary embodiment.

FIG. 41 illustrates a plan view of the pre-form after having carried out a half cut through a leadframe before final finishing.

FIG. 42 illustrates a plan view of the pre-form after having carried out a final cut through the laminate with a thinner blade.

FIG. 43 illustrates a three-dimensional view of a portion of a package manufactured according to FIG. 40 to FIG. 42 so as to be provided with a stepped edge.

FIG. 43A illustrates a cross-sectional view showing the two mentioned cutting procedures according to FIG. 41 and FIG. 42.

FIG. 44 illustrates a plan view of a detail of a pre-form of a package according to an exemplary embodiment.

FIG. 45 illustrates a three-dimensional view of a part of the package being provided with an electrically conductive stop layer exposed by a via hole.

FIG. 46 illustrates a plan view of a metallic sheet with vias as a basis for a package according to the described exemplary embodiment.

FIG. 47 illustrates a plan view of a package after lamination and pad formation as well as singularization according to an exemplary embodiment corresponding to a circular through hole design.

FIG. 48 illustrates a plan view of a package according to another exemplary embodiment which differs from the embodiment of FIG. 47 by the fact that the via holes according to FIG. 48 have a rounded rectangular cross section.

FIG. 49 illustrates a plan view of a detail of a pre-form of a package according to an exemplary embodiment.

FIG. 50 illustrates a three-dimensional view of a part of the package being provided with an electrically conductive stop layer exposed by a via hole.

FIG. 51 illustrates a plan view of a pre-form of a package after lamination and pad formation according to an exemplary embodiment.

FIG. 52 illustrates a plan view of a pre-form of a package after laser cleaning and surface finishing of the pre-form according to FIG. 51.

FIG. 53 illustrates a plan view of package after dicing or singularization.

FIG. 54 illustrates a bottom side and FIG. 55 illustrates a top side of a package according to an exemplary embodiment.

FIG. 56 illustrates a cross-sectional view of the package according to FIG. 54 and FIG. 55 before soldering.

FIG. 57 illustrates a cross-sectional view of an arrangement composed of a mounting base and of the package according to FIG. 54 to FIG. 56 according to an exemplary embodiment after soldering.

FIG. 58 to FIG. 60 illustrate cross sectional view of portions of a respective package with lead tip inspection capability according to exemplary embodiments.

FIG. 61 illustrates a cross-sectional view of a detail of and a plan view of a pre-form of multiple packages during singularization according to an exemplary embodiment.

FIG. 62 illustrates a cross-sectional view of a detail of and a plan view of a pre-form of multiple packages during singularization according to an exemplary embodiment.

FIG. 63 and FIG. 64 illustrate a portion of a package according to an exemplary embodiment in different stages during processing.

FIG. 65 illustrates a detail of the package according to FIG. 64 after soldering.

FIG. 66 illustrates a detail of a package according to an exemplary embodiment.

FIG. 67 illustrates a detail of a package similar to FIG. 63 after soldering.

FIG. 68 illustrates a plan view of a pre-form of multiple packages according to an exemplary embodiment.

FIG. 69 illustrates a cross-sectional view of a portion of the pre-form according to FIG. 68.

FIG. 70 illustrates a detail of FIG. 69 after plating.

FIG. 71 illustrates a cross-sectional view of a portion of an arrangement according to an exemplary embodiment based on the package of FIG. 70.

### DETAILED DESCRIPTION OF EXEMPLARY EMBODIMENTS

The illustration in the drawing is schematically and not to scale.

Before exemplary embodiments will be described in more detail referring to the figures, some general considerations will be summarized based on which exemplary embodiments have been developed.

According to an exemplary embodiment, chip embedding with lead tip inspection is made possible.

Conventionally, it is difficult to optically control solder positions of power semiconductor packages. In conventional chip embedding packaging concepts, the desired optical controllability of soldering positions is not always possible, in particular when the corresponding contact positions are only provided on one surface of the package (for instance, on the bottom main surface of the package). After surface mounting of the embedded package on a mounting base such as a PCB, the solder positions are no longer visible and must conventionally be checked with expensive and cumbersome X-ray investigations.

In contrast to this, according to an exemplary embodiment of the invention, control of one or more contact positions can be carried out with chip embedding packages by a simple optical control. According to an embodiment, this can be accomplished by forming one or more metallic structures such as copper vias in a subsequent edge portion of a package of a pre-form of multiple such packages. After singularization of the pre-form into various packages (for instance by sawing), such metallic structures are separated and thereby exposed at lateral side edges of the singularized packages. Thus, the separated and exposed structures can serve as wettable surface regions and may be used for optical control purposes.

Hence, according to an exemplary embodiment of the invention, chip embedding technology may be equipped with a lead tip inspection function which may be configured particularly as a metallized laminate region in an edge portion of the package. Such an edge portion may be formed based on copper vias separated during package singularization. Gold, silver, nickel, palladium, platinum and/or tin coated solderable electric contacts of the housing may be used correspondingly.

According to exemplary embodiments of the invention, an embedded package with lead tip inspection opportunity is provided. A corresponding structure, which may contribute to a solder flow path, may allow automated optical inspection of the solder joint quality (for instance wetting properties, etc.). Such a feature is desired in many application areas (for instance automotive applications) where reliable quality is required in high volume production. In case the solder pads are located underneath the package (like for example in BGA, ball grid array, packaging technology) the soldering result and/or quality (in particular in terms of wetting) must be conventionally done using X-ray equipment instead of fast automatic optical inspection (AOI) or visual inspection equipment.

In conventional laminate type packages, lead tip inspection is not possible, since the solder pads are underneath the package. In many design architectures, dicing only though the laminate is allowed. Even in case the dicing would be done also through the copper material to reveal copper pads on the edge of the package module (which is however not preferred and may even not be allowed by design rules due to dicing and delamination problems), the copper thickness (in case of plated copper) may be also too thin for lead tin inspection (for instance only 20 μm or less). Furthermore, the side of the pad might not have a wettable surface.

In order to overcome such shortcomings, structures according to exemplary embodiments of the invention may allow to reveal (for example by one or more slots, holes, half cut) and/or to plate a copper lead on the edge of the package that can be plated with solderable surface finishing and can be used for optical inspection of the solder joint.

According to an exemplary embodiment of the invention, it is possible to manufacture slots and/or though holes either to the pads (all or only corner) or the edge of the pads (for instance by dicing from the center of the pads/slots) before plating or surface finishing. Wettable structures on the side of the package can be used to detect optically how good the wetting of the solder is (for example by measuring the solder filling or the solder meniscus on the side contact). Such structures can be manufactured with dicing (for example by half cut), drilling (for instance mechanically, by laser treatment, etc.) or routing. The structure of a lead tip inspection pad depends on the process used, structures underneath and/or inside the module and when the hole and/or the slot has been made (for example before copper plating or after plating).

According to an exemplary embodiment of the invention, an embedded package with a leadframe as footprint may be provided.

In order to adjust the resistance and the impedance, a metallic structure of a certain thickness and geometry may be used as chip carrier on which the electronic chip is or the electronic chips are bonded. According to an exemplary embodiment, this is realized by an embedded electronic chip bonded on a chip carrier, wherein the footprint is defined directly by the chip carrier. By taking this measure, a thermally properly coupled system is obtained in which the chip carrier can be electrically connected by a low-ohmic and a low-impedance connection by vias and a redistribution layer. In this embodiment, a passive and/or active component may be used by soldering on an electronic member. Moreover, such an architecture may allow for a lead tip inspection functionality. In the described embodiment, the metal carrier itself may advantageously define the footprint.

In a corresponding embodiment, the electronic chip may be bonded on the chip carrier, for example by a solder or an adhesive connection. The chip carrier may be made subject to partial etching, for instance can be through etched from the backside. Alternatively, the chip carrier may be provided without etching, and patterning may be carried out by a complete backside etching. In yet another exemplary embodiment, the chip carrier may be fully patterned. Isolated islands can then be realized by a through bore. After die attach, a one-sided lamination can be carried out with subsequent placing and redistribution layer patterning.

In other exemplary embodiments, one or more further redistribution layers may be formed on one side or both sides of the package.

It is also possible to provide a passive component on top. More specifically, the passive component may be selected so that an impedance matching of the conductive path to the chip is realized or that passive components are shifted from the board to the system. The thermal coupling can be further improved by an exposed pad, whereas one or more redistribution layers can optimize impedance and resistance.

In particular, the described architecture is properly compatible with a lead tip inspection capability. When the patterning of the chip carrier is carried out so that the package flushes with the metal carrier, a proper basis for a lead tip inspection capability is made. This means that the optical control of the solder quality can be easily made by an optical inspection.

In yet another exemplary embodiment, an embedded power LGA (land grid array) with a lead tip inspection capability is provided. Structures according to such an embodiment allow an automatic optical inspection of the solder joint quality (for instance wetting). This is a feature that is advantageous in many application areas (for example automotive, high voltage industrial products, AC/DC) in high volume production. In case the solder pads are underneath the package (like for example in BGA, ball grid array) the soldering result quality (in particular in terms of wetting) must be conventionally done using X-ray equipment instead of fast automatic optical inspection (AOI) or visual inspection equipment. In conventional packages, lead tip inspection may be not possible, since the solder pads are located underneath the package.

Provisions made according to an embodiment allow to reveal copper structures on the edge of the package that can be plated with solderable surface finish and can be used for optical inspection of the solder joint.

An exemplary embodiment is based on the gist to generate copper structures in a relatively thick copper layer close to or directly at the edge of a package. These structures may be plated with a solderable surface finish during a plating process of the components. As a further option, the copper structures may even exceed the package edge and may be bent upwards along the package edge. This may create a solderable surface very close to or directly at the edge of the package. This ensures AOI capability after board assembly.

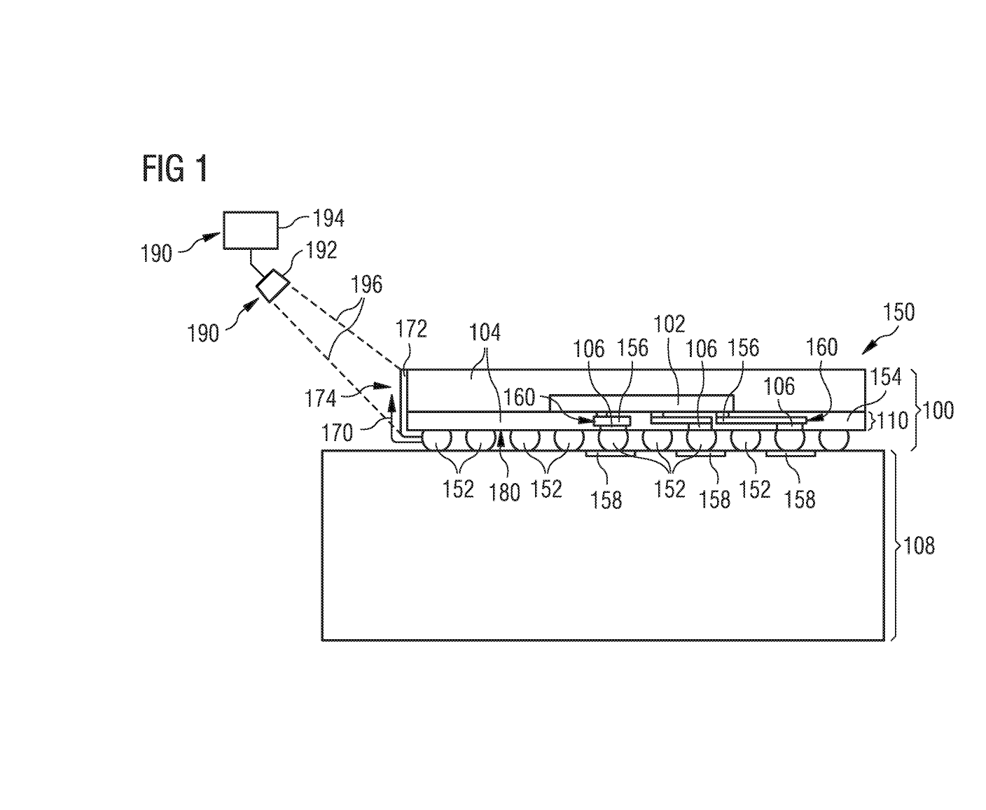

FIG. 1 illustrates a cross-section of an arrangement 150 comprising an embedded package 100 on a mounting base 108 as well as an optical inspection device 190 according to an exemplary embodiment. FIG. 1 hence illustrates a cross-section of the arrangement 150 composed of the package 100 with an embedded electronic chip 102 (wherein other embodiments may embed a plurality of electronic chips 102 and/or may surface mount one or a plurality of electronic chips 102) and of the mounting base 108 which is electrically and mechanically connected to the package 100 by soldering.

More specifically, the package 100 is embodied as semiconductor power package. Consequently, the electronic chip 102 can be a power semiconductor chip (for instance having integrated therein one or more diodes, one or more transistors such as IGBTs, etc.). In the shown embodiment, the mounting base 108 may be embodied as a printed circuit board, PCB) comprising solder pads 158. As shown, the package 100 is mounted on the mounting base 108 by establishing a solder connection between solderable exterior electric contacts 106 (which may also be denoted as pads, compare reference numeral 2302 in several below described embodiments) of the package 100 on the one hand and the solder pads 158 of the mounting base 108 on the other hand. FIG. 1 moreover shows solderable structures 152 between the electric contacts 106 and the solder pads 158 as additional solder depot.

Formation of a solder connection between the package 100 and the mounting base 108 may for instance be accomplished by placing the package 100 on the mounting base 108 so that the electric contacts 106 and the solder pads 158 are aligned and by subsequently supplying thermal energy (for instance in a solder oven). This temporarily melts solder material 152 around the electric contacts 106 and the solder pads 158 and, after re-solidification, results in the solder connection.

The package 100 embeds or encapsulates the electronic chip 102 in a laminate-type encapsulant 104. The laminate-type encapsulant 104 may be composed of a plurality of electrically insulating layers (for instance made of prepreg or FR4), which may be interconnected by lamination (for instance by applying pressure at an elevated temperature). The above-mentioned solderable exterior electric contacts 106 at an exterior surface of the package 100 are electrically coupled with the electronic chip 102 via a redistribution layer 110. More specifically, a wiring structure 160 (for instance composed of several interconnected electrically conductive elements, in particular made of copper) may be provided which is embedded in a dielectric matrix 154 and extends from the electronic chip 102 up to a contact pad 156 or even up to the electric contacts 106 of the wiring structure 160.

For certain applications, it is desired to have the capability of visually or optically monitoring properties (such as wettability, quality, etc.) of the solder connection. However, as can be taken from the cross-sectional view of FIG. 1, the position of the solder connections between elements 106, 152, 158 is no longer visually accessible due to the close spatial vicinity between a solder surface 180 of the package 100 and the corresponding upper main surface of the mounting base 108 facing the solder surface 180. Visual inspectability of the solder connection is further rendered complicated by the fact that the solderable electric contact 106 may have a very small surface area of for example 200 μm×300 μm.

However, it will be described in the following how, according to the shown exemplary embodiment of the invention, an optical inspection device 190 can be nevertheless arranged for optically inspecting solder material 152. This can be accomplished by forcing, causing or triggering flow of soldered material from elements 106, 152, 158 to an optically inspectable surface 174 of the package 100. The optically inspectable surface 174 is, according to the embodiment of FIG. 1, a vertical lateral surface of the package 100 which remains optically accessible even after having established the solder connection between package 100 and mounting base 108. A part of the solder material 152 has correspondingly flown from the solder surface 180 to the optically inspectable surface 174 of the package 100 along a solder flow path 170. The solder flow path 170 is here located along an exterior surface of the package 100 and is made of a solder-wettable structure 172 ensuring that, upon soldering the electric contacts 106 with the mounting base 108, part of the solder material 152 flows along the solder flow path 170 towards the lateral vertical surface of the package 100 at which the solder material 152 is optically inspectable by the optical inspection device 190 after completion of the solder connection between the mounting base 108 and the electric contact 106.

The optical inspection device 190 comprises a camera 192 (for instance operating in the range of visible light, infrared radiation, ultraviolet radiation, etc.) and a corresponding image processing unit 194 which is configured for processing the images captured by the camera 192 of the optically inspectable surface 174 of the package 100. On the basis of the captured images and by carrying out image processing (for example in accordance with a software code), the image processing unit 194 is configured for outputting data indicative of at least one property of the solder connection (such as wettability, quality, etc.).

As can be taken from FIG. 1, the configuration of the solder flow path 170 ensures that a continuous line of sight (see reference numeral 196) is created or maintained between the optical inspection device 190 and the optically inspectable surface 174 regardless of the close spatial vicinity of the solder connected opposing main surfaces of the package 100 and the mounting base 108. By an optical detection along a continuous line of sight, a simple non-invasive (in terms of the propagation of electromagnetic radiation) solder inspection is made possible. This is highly preferred over a conventional cumbersome invasive solder inspection using X-rays.

According to the shown embodiment, the solder flow path 170 from the solder surface 180 up to the optically inspectable surface 174 is created or defined by the solder-wettable structure 172 in contact with the encapsulant 104 and arranged so that, upon soldering the electric contact 106, part of the solder material 152 flows onto the solder-wettable structure 172. As can be seen from FIG. 1, the solder-wettable structure 172 is located also at the optically inspectable surface 174 of the package 100 which is visually inspectable after completion of the solder connection of the package 100 on the mounting base 108. For example, the solder flow path 170 may be manufactured by plating a corresponding surface portion of the package 100 with solder-wettable material such as silver, gold, nickel, palladium and/or tin, to thereby form the solder-wettable structure 172. As can be taken from FIG. 1, the solder flow path 170 is located partially on a sidewall and partially on the solder surface 180 of the package 100. Consequently, the solder flow path 170 is continuously connected with one or more of the solderable electric contacts 106 by solderable material.

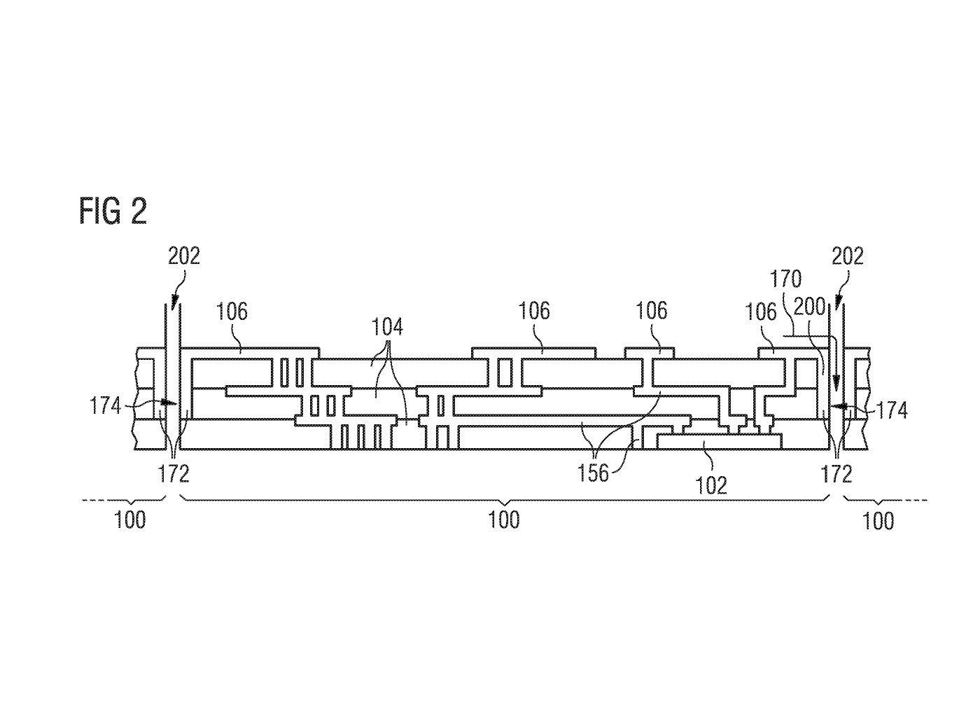

FIG. 2 illustrates a cross-sectional view of a package 100 according to another exemplary embodiment. According to FIG. 2, the solder flow path 170 for this package 100 is defined by a portion of a vertical through-connection 200 exposed on a side surface of the package 100. Upon singularizing the shown pre-form of multiple packages 100 by dicing along separation lines 202, the vertical through connections 200 (such as plated or entirely filled vias) are cut axially into two substantially identical halves with solder-wettable structures 172 on vertical lateral surfaces of the singularized packages 100. The simultaneous execution of singularization and formation of the solder-wettable structures 172 allows for a very efficient provision of optical inspectability.

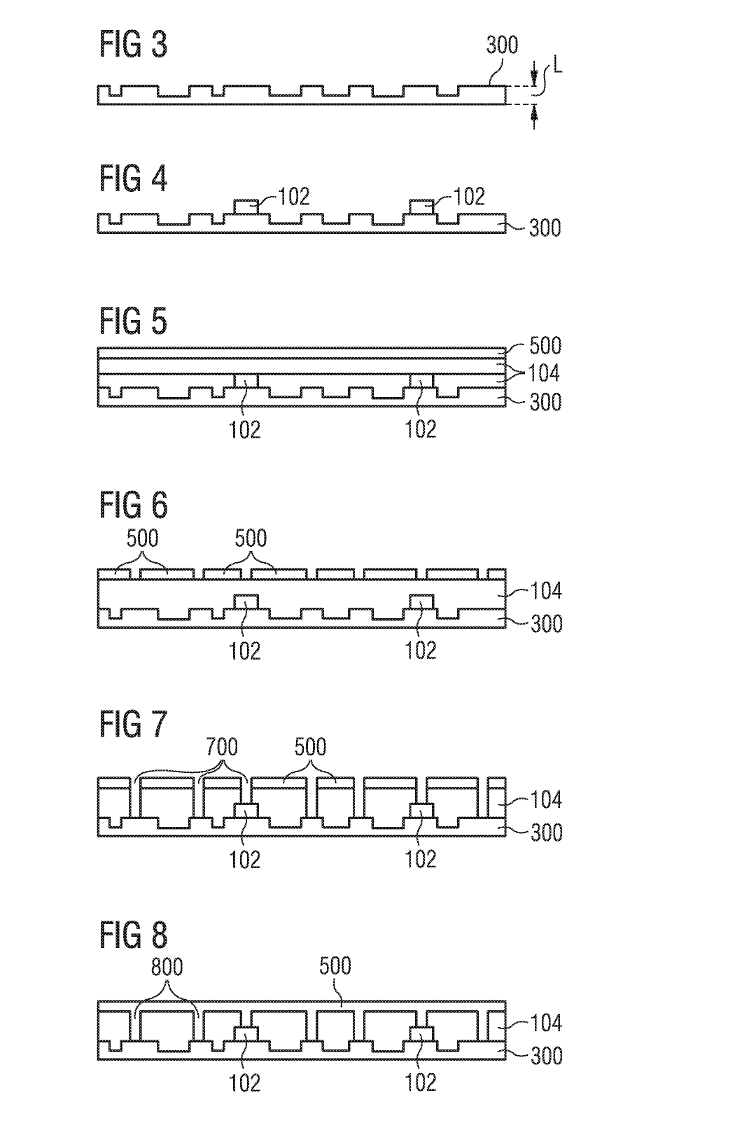

FIG. 3 to FIG. 12 illustrate structures obtained during carrying out a method of manufacturing a package 100 according to an exemplary embodiment.

In order to obtain the structure shown in FIG. 3, a patterned chip carrier 300 may be provided as a support for multiple electronic chips 102. For example, the chip carrier 300 may be a leadframe, for instance made of copper. Preferably, the chip carrier 300 has a sufficiently large vertical height, L, of for example at least 250 μm. More generally, a thickness of the chip carrier 300 may be preferably in a range between 20 μm and 500 μm. A sufficiently high thickness, L, will promote usability of a vertical lateral surface of the chip carrier 300 to function as solder flow path 170 (see FIG. 14 to FIG. 17).

In order to obtain the structure shown in FIG. 4, multiple electronic chips 102 are attached to an upper main surface of the chip carrier 300. This die attach procedure may be carried out before or after copper roughening.

In order to obtain the structure shown in FIG. 5, the structure according to FIG. 4 is encapsulated using a laminate-type encapsulant 104. This may involve laminating a plurality of dielectric layers forming the laminate-type encapsulant 104. Moreover, an electrically conductive layer 500 may be laminated on top of the structure shown in FIG. 5, for example a copper foil.

In order to obtain the structure shown in FIG. 6, the electrically conductive layer 500 is patterned.

In order to obtain the structure shown in FIG. 7, a plurality of via holes 700 are drilled in the encapsulant 104 to expose surface portions of the chip carrier 300.

In order to obtain the structure shown in FIG. 8, the via holes 700 are filled with electrically conductive material, thereby forming a plurality of vias 800 (which may be done by via plating).

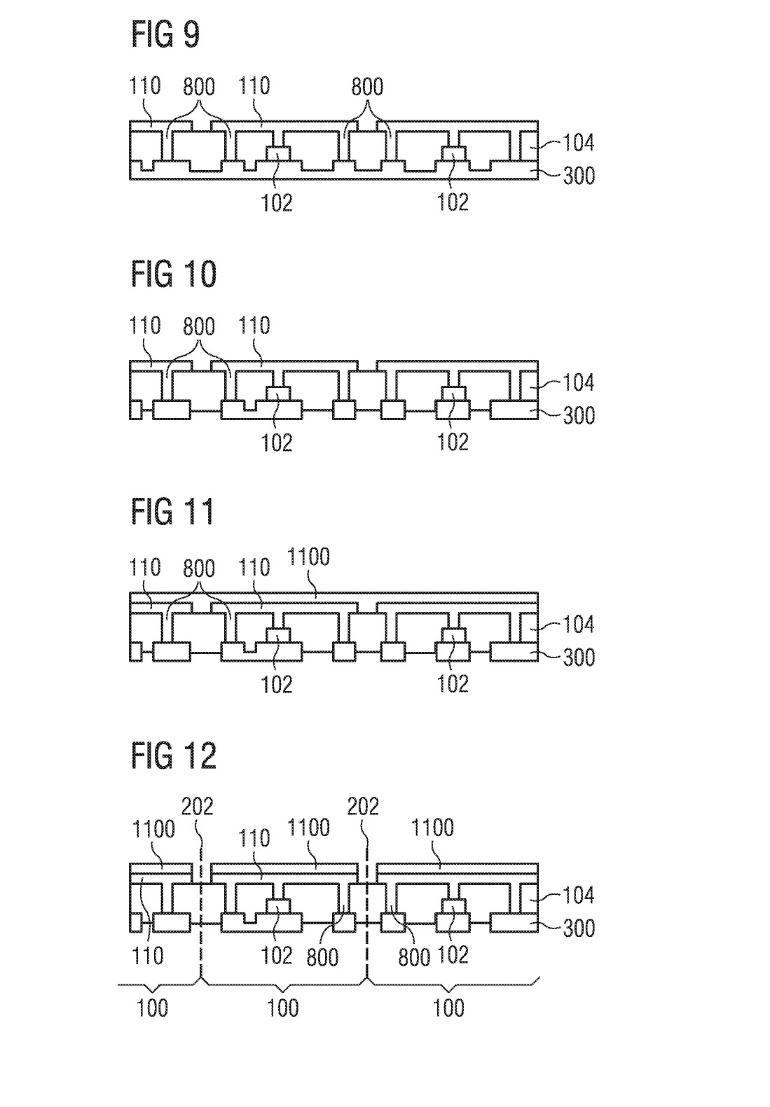

In order to obtain the structure shown in FIG. 9, electrically conductive material on an upper main surface of the structure shown in FIG. 8 is patterned by etching, thereby forming part of a redistribution layer 110.

In order to obtain the structure shown in FIG. 10, the chip carrier 300 is patterned, thereby forming an etched leadframe extending laterally partially within and partially outside of the encapsulant 104.

In order to obtain the structure shown in FIG. 11, a solder resist 1100 is formed to cover the upper main surface of the structure according to FIG. 10.

In order to obtain the structure shown in FIG. 12, the structure according to FIG. 11 is singularized, for instance by sawing, into a plurality of individual packages 100 (see separation lines 202).

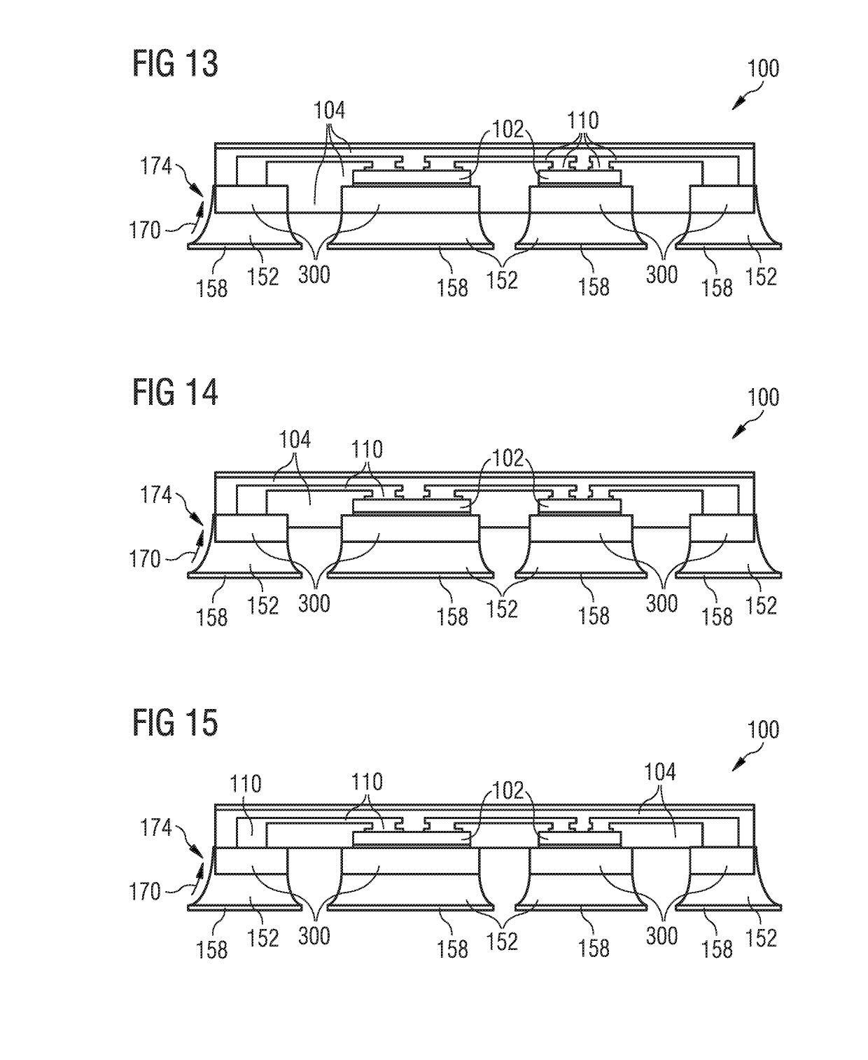

FIG. 13 illustrates a cross-sectional view of a package 100 according to an exemplary embodiment. Package 100 according to FIG. 13 may be manufactured in a corresponding way as shown referring to FIG. 3 to FIG. 12. According to FIG. 13, the solder flow path 170 is defined by an exposed lateral vertical surface of the chip carrier 300, here embodied as a leadframe, on which the electronic chips 102 are mounted. The embodiment of FIG. 13 corresponds to a package 100 with lead tip inspection capability with a fully patterned leadframe as metallic chip carrier 300. Preferably, the leadframe should have a height of at least 250 μm in order to render optical inspection of its sidewall feasible with high precision. According to FIG. 13, a lower main surface of the chip carrier 300 flushes with a lower main surface of the encapsulant 104.

FIG. 14 illustrates a cross-sectional view of a package 100 according to another exemplary embodiment. The embodiment of FIG. 14 corresponds to a package 100 with lead tip inspection capability with a half etched leadframe as metallic chip carrier 300. According to FIG. 14, a part of the chip carrier 300 is located with the encapsulant 104 and another part of the chip carrier 300 is located outside of the encapsulant 104.

FIG. 15 illustrates a cross-sectional view of a package 100 according to still another exemplary embodiment. The embodiment of FIG. 15 is a package 100 with lead tip inspection capability with a non-patterned leadframe as metallic chip carrier 300. According to FIG. 15, the chip carrier 300 is located entirely outside of the encapsulant 104.

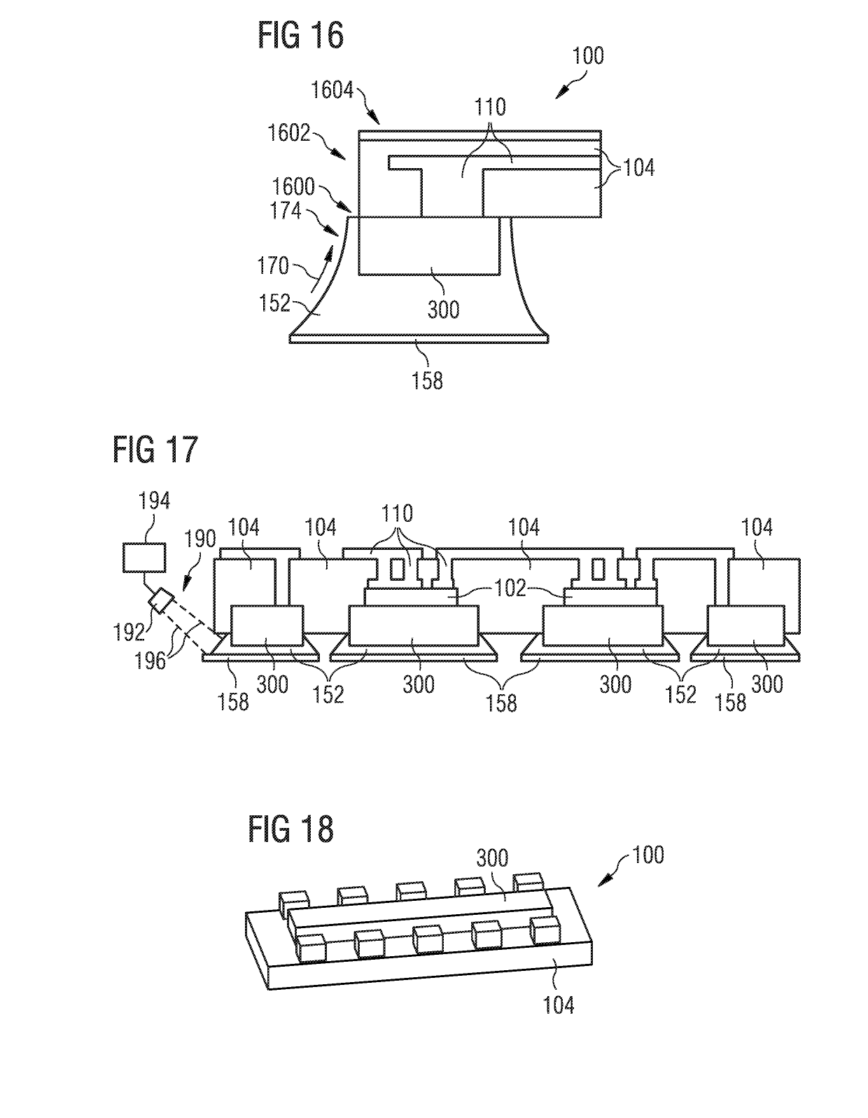

FIG. 16 illustrates a cross-sectional view of a detail of a package 100 according to an exemplary embodiment. According to FIG. 16, the solder material 152 has climbed vertically up to a position 1600 at an upper end of the chip carrier 300. However, alternatively, the solder flow path 170 may be defined up to a vertically higher position on the lateral surface of the package 100 (see reference numeral 1602), or even up to a top surface of the package 100 (see reference numeral 1604). This can be adjusted by adjusting a spatial extension of the solder-wettable structure 172.

FIG. 17 illustrates a cross-sectional view of a package 100 according to yet another exemplary embodiment. As can be taken from FIG. 17, wetting a lateral surface of the chip carrier 300 may still allow an optical inspection of the quality of the solder material 152 and the wetting properties by an optical inspection device 190, or by a human operator (not shown). As can be taken from FIG. 17, all free or exposed (plated) portions of the chip carrier 300 are wetted with solder material 152.

FIG. 18 illustrates a three-dimensional view of a package 100 according to an exemplary embodiment before soldering. After soldering, some or all of the shown exposed surface portions of the chip carrier 300 will be covered by solder material 152.

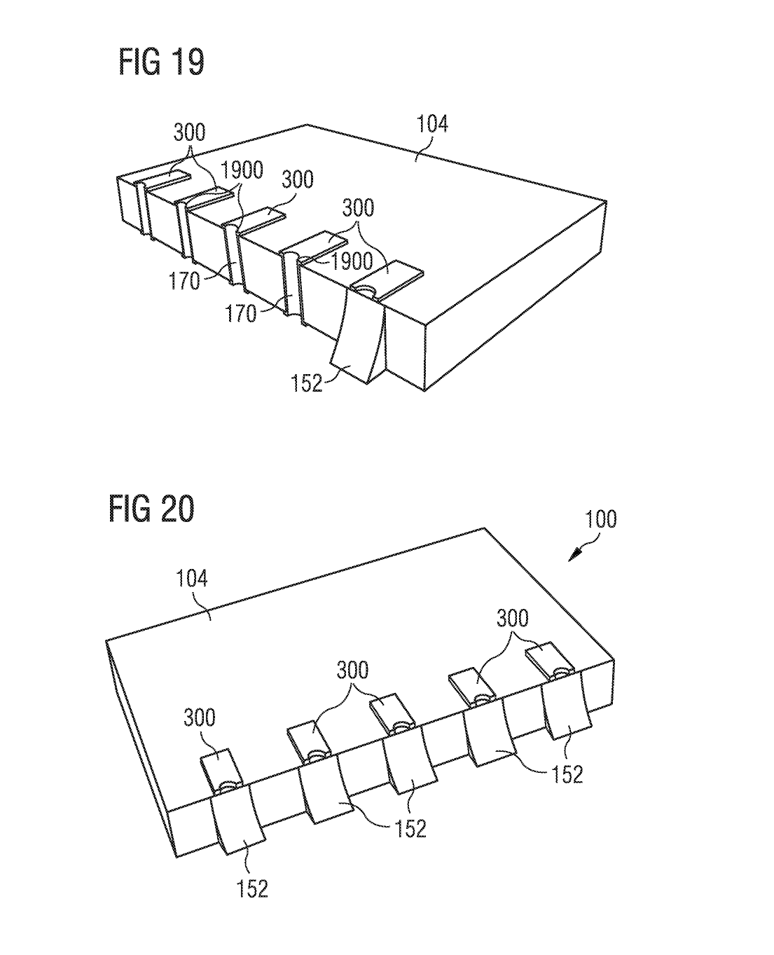

FIG. 19 illustrates a three-dimensional view of a package 100 according to an exemplary embodiment with and without solder connection. In FIG. 19, a meniscus of solder material 152 is shown which may be used for optical inspection. Furthermore, plated through holes 1900 with a concave surface curvature are shown which can be used efficiently as well defined solder flow paths 170.

FIG. 20 illustrates a three-dimensional view of a package 100 according to an exemplary embodiment with solder connection. FIG. 20 is another illustration of the embodiment of FIG. 19, but shows all exposed surface portions of the chip carrier 300 covered with solder material 152.

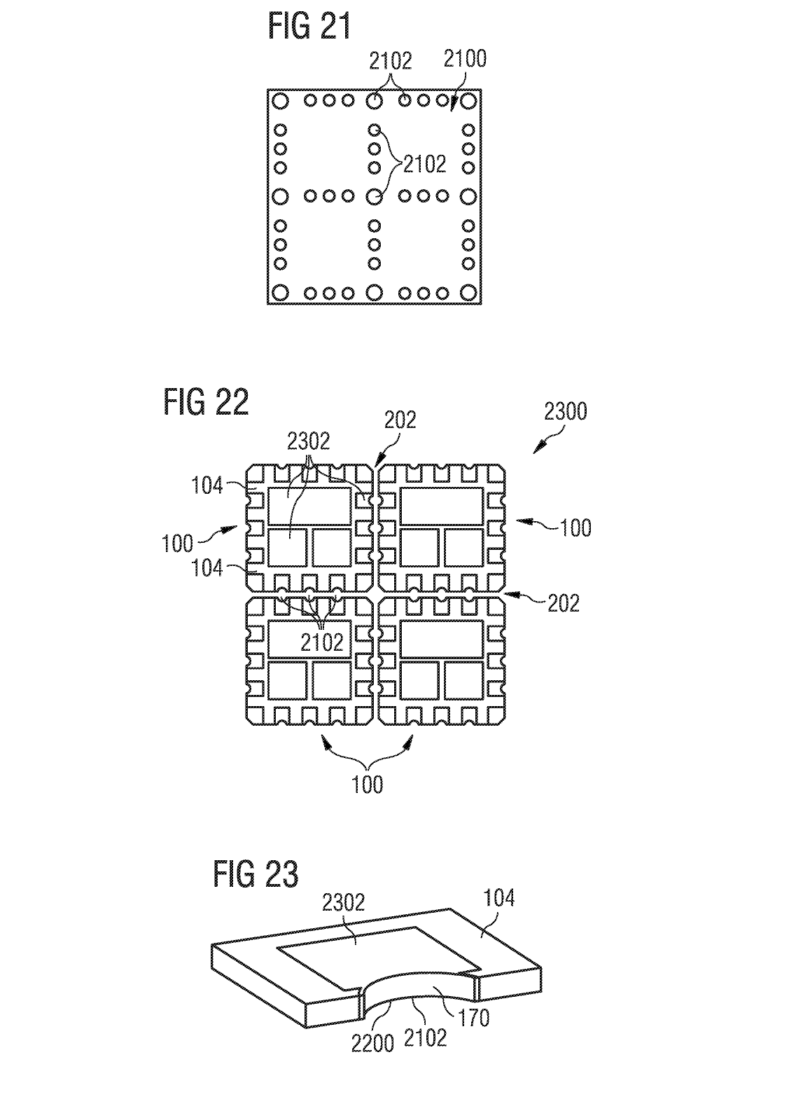

A further exemplary embodiment of a package 100 will be described referring to FIG. 21 to FIG. 25. This embodiment is based on through hole formation on a dicing street before patterning a metallic sheet 2100 and results in a stamp-shaped design.

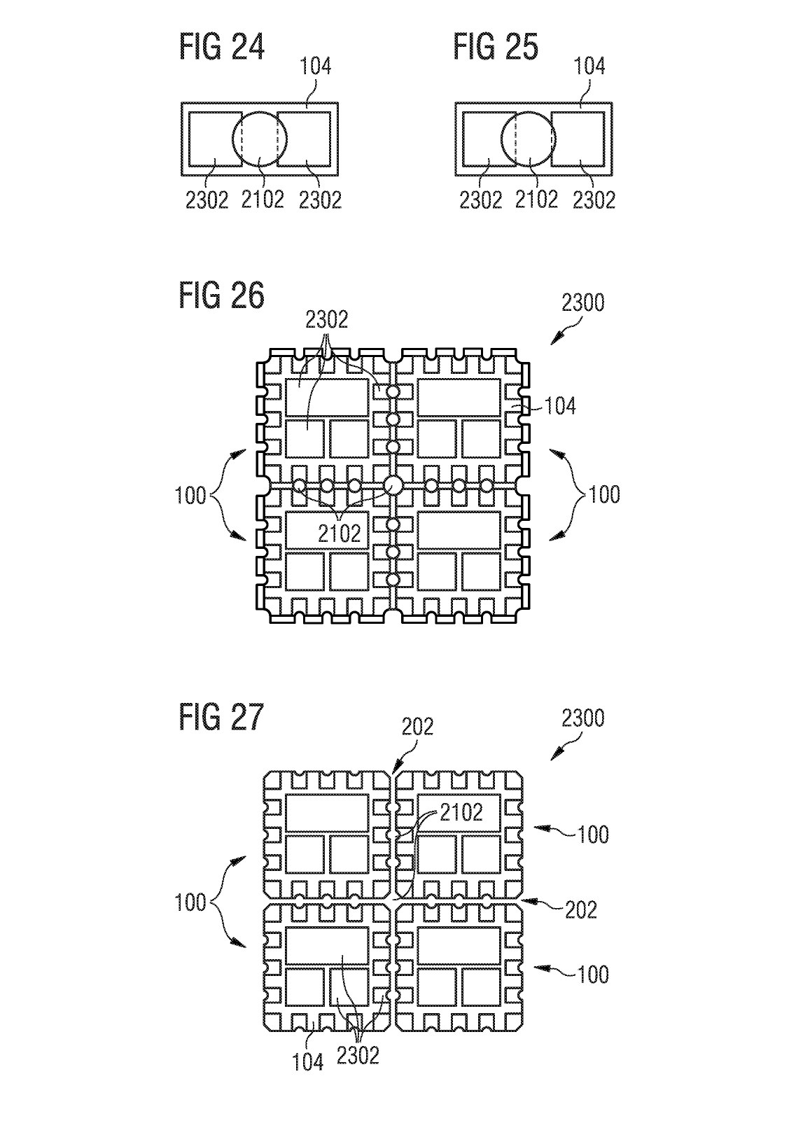

FIG. 21 illustrates a plan view of the metallic sheet 2100 (for instance made of copper) with drilled through holes 2102 used as a basis for packages 100 according to an exemplary embodiment. The through holes 2102 may be drilled on a dicing street and may be plated (for instance with a solder-wettable material such as gold). FIG. 22 illustrates a corresponding plan view of a pre-form 2300 of multiple packages 100 after singularization. Portions of the plated metallic sheet 2100 form or may be electrically connected to pads 2302 (which may be configured or may be identical to electric contacts 106, as shown for example in FIG. 1). Before singularizing, the packages 100 have been encapsulated in laminate-type encapsulant 104 (such as prepreg or FR4). During singularization, cutting along cutting lines 202 and hence along the through holes 2102 has been carried out so as to obtain packages 100 with a stamp-shaped perimeter. FIG. 23 illustrates a three-dimensional view of a detail of a pad 2302 embedded in encapsulant 104 and being provided with a through hole 2102. FIG. 24 illustrates a plan view of a portion of the structure according to FIG. 22 before singularization without offset, i.e. with a through hole 2102 in a central or symmetric position between two packages 100. FIG. 25 illustrates a plan view of a portion of the structure according to FIG. 22 before singularization with offset, i.e. with a through hole 2102 in a decentralized or asymmetric position between two packages 100. FIG. 24 and FIG. 25 relate to an architecture in which one through hole 2102 is shared between two modules or packages 100. One central through hole 2102 in FIG. 22 is even shared among four packages 100.

Thus, the embodiment of FIG. 21 to FIG. 25 for manufacturing lead tip inspection structures is based on the formation of through holes 2102 on an edge of pads 2302 before plating and on the cutting from a center of the pads 2302. According to FIG. 21 to FIG. 25, the solder flow path 170 comprises a cavity 2200 configured so that solder material 152 (not shown in FIG. 21 to FIG. 25) flows into the cavity 2200 upon soldering for being optically inspected there. Moreover, the solder flow path 170 is here formed partially before and partially during singularizing pre-form 2300 of multiple packages 100 into individual packages 100. Consequently, the solder flow path 170 is formed in the described embodiment by drilling and is exposed by dicing.

Still another exemplary embodiment of a package 100 will be described referring to FIG. 26 to FIG. 30. This embodiment is based on through hole formation on a dicing street after patterning and also results in a stamp-shaped design.

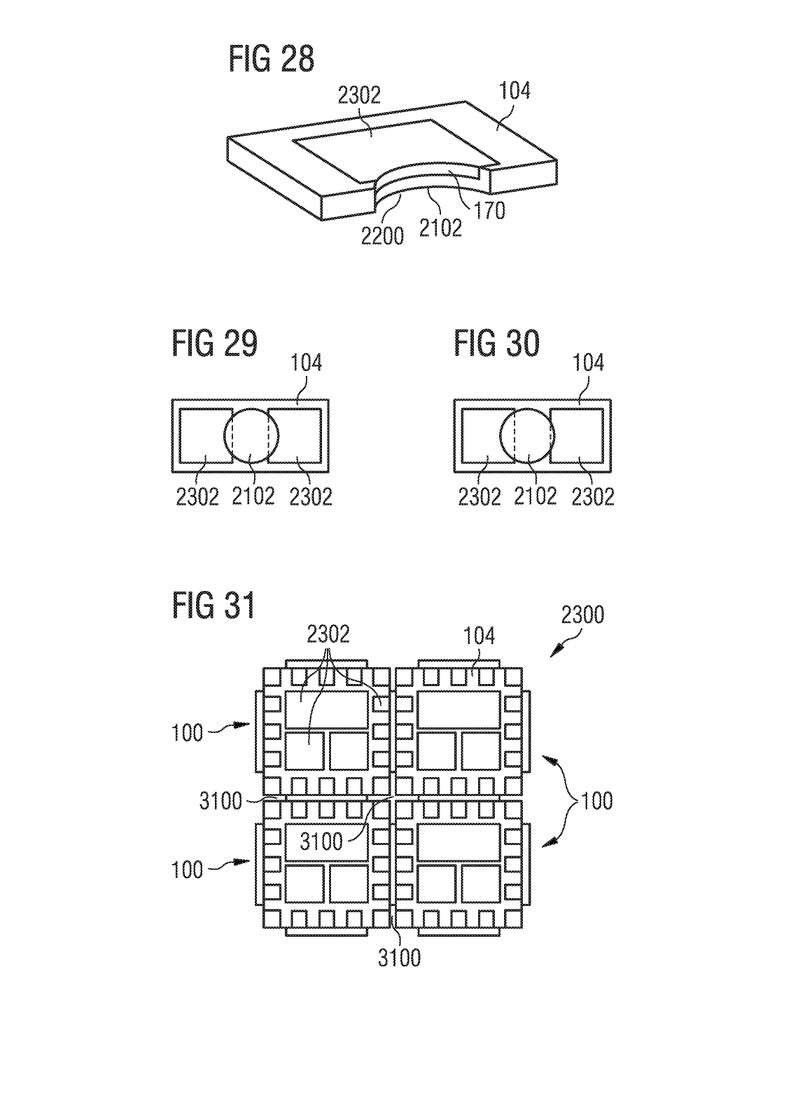

FIG. 26 illustrates a plan view of a pre-form 2300 of multiple packages 100 with drilled through holes 2102 used as a basis for packages 100 according to an exemplary embodiment. The through holes 2102 may be drilled on a dicing street after patterning and before final finishing. No dicing is hence necessary through copper material. FIG. 27 illustrates a corresponding plan view of the pre-form 2300 of multiple packages 100 after singularization. Again, the packages 100 have been encapsulated in laminate-type encapsulant 104. During singularization, cutting along cutting lines 202 and hence along the through holes 2102 has been carried out. FIG. 28 illustrates a three-dimensional view of a detail of a pad 2302 embedded in encapsulant 104 and being provided with a through hole 2102. Contrary to FIG. 23, a bottom of the pad 2302 rests on material of the encapsulant 104 according to FIG. 28. According to FIG. 28, only a portion of the vertical curved surface of the shown structure defined by the through hole 2102 comprises solder-wettable material. FIG. 29 illustrates a plan view of a portion of the structure according to FIG. 28 before singularization without offset, i.e. with a through hole 2102 in a central or symmetric position between two packages 100. FIG. 30 illustrates a plan view of a portion of the structure according to FIG. 28 before singularization with offset, i.e. with a through hole 2102 in a decentralized or asymmetric position between two packages 100. FIG. 29 and FIG. 30 relate to an architecture in which one through hole 2102 is shared between two modules or packages 100. One central through hole 2102 in FIG. 27 is even shared among four packages 100.

Thus, the embodiment of FIG. 26 to FIG. 30 for manufacturing lead tip inspection structures is based on the manufacture of through holes 2102 after plating and structuring but before final finishing. A benefit of a corresponding manufacturing process is that the package separation can be done only by cutting through laminate material allowing a higher cutting speed and no risk caused by possible delamination of copper material during package separation.

Instead of drilling through holes 2102 according to FIG. 21 to FIG. 30, it is also possible to form slots by mechanical routing (or by laser routing). This can be carried out at the edges (or edge portions) and/or at the corners (or corner portions) of a respective module or package 100, including one or some or all of the respective pads 2302. This can be carried out after patterning (see embodiments according to FIG. 31 to FIG. 39), before patterning or before plating, etc. In case the pads 2302 are manufactured after plating, the plated edge contact may be only as thick as the conductor or the leadframe. However, this allows to manufacture slots that reveal several contact pads 2302 at the same time (the solderable final finishing may be plated only on the revealed metal surfaces).

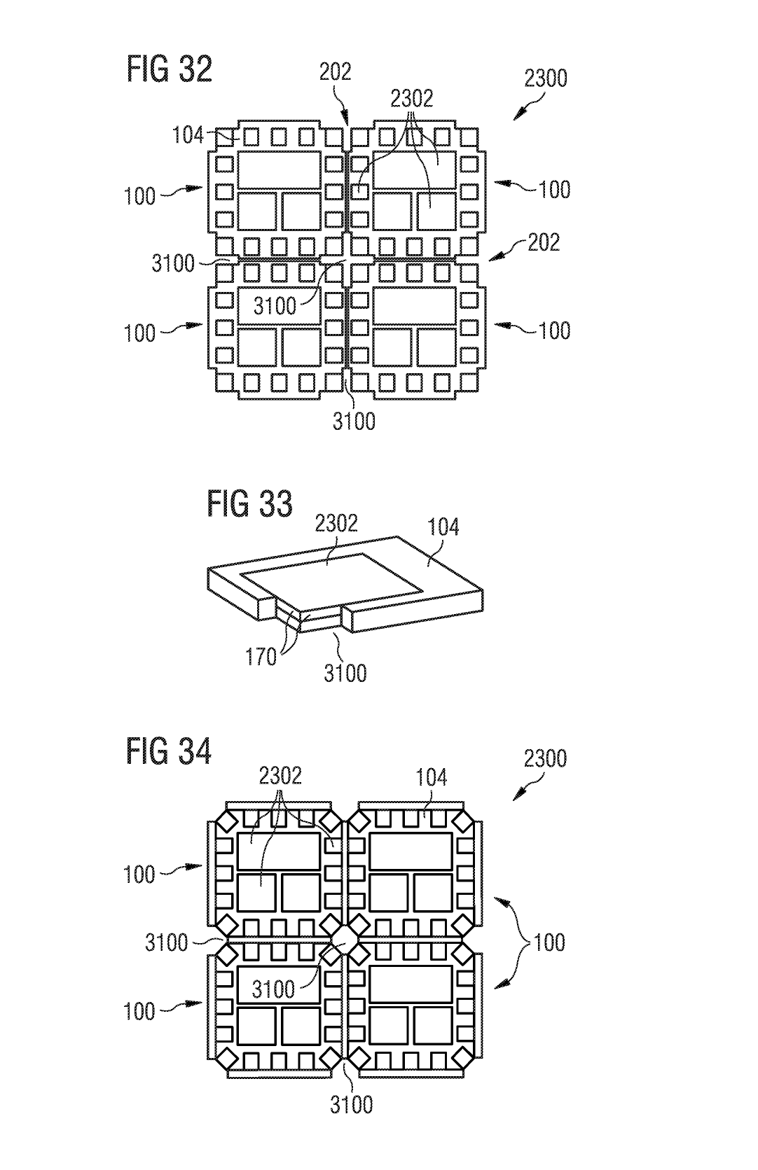

FIG. 31 illustrates a plan view of a pre-form 2300 of multiple packages 100 with routed slots 3100 (having a cross or “+” shape in the plan view of FIG. 31) used as a basis for packages 100 according to an exemplary embodiment. The routed slots 3100 may be routed on the corners between adjacent packages 100 of the pre-form 3100 after patterning and before final finishing. FIG. 32 illustrates a corresponding plan view of the pre-form 2300 of multiple packages 100 after singularization by cutting along cutting lines 202. Again, the packages 100 have been encapsulated in a laminate-type encapsulant 104. During singularization, cutting along the cutting lines 202 and hence along the routed slots 3100 has been carried out. FIG. 33 illustrates a three-dimensional view of a detail of a pad 2302 embedded in encapsulant 104 and being provided with a routed slot 3100 in a corner. Either the whole or only a part of the corner pad 2302 is opened. Inspection is hence carried out on a respective corner of the respective package 100.

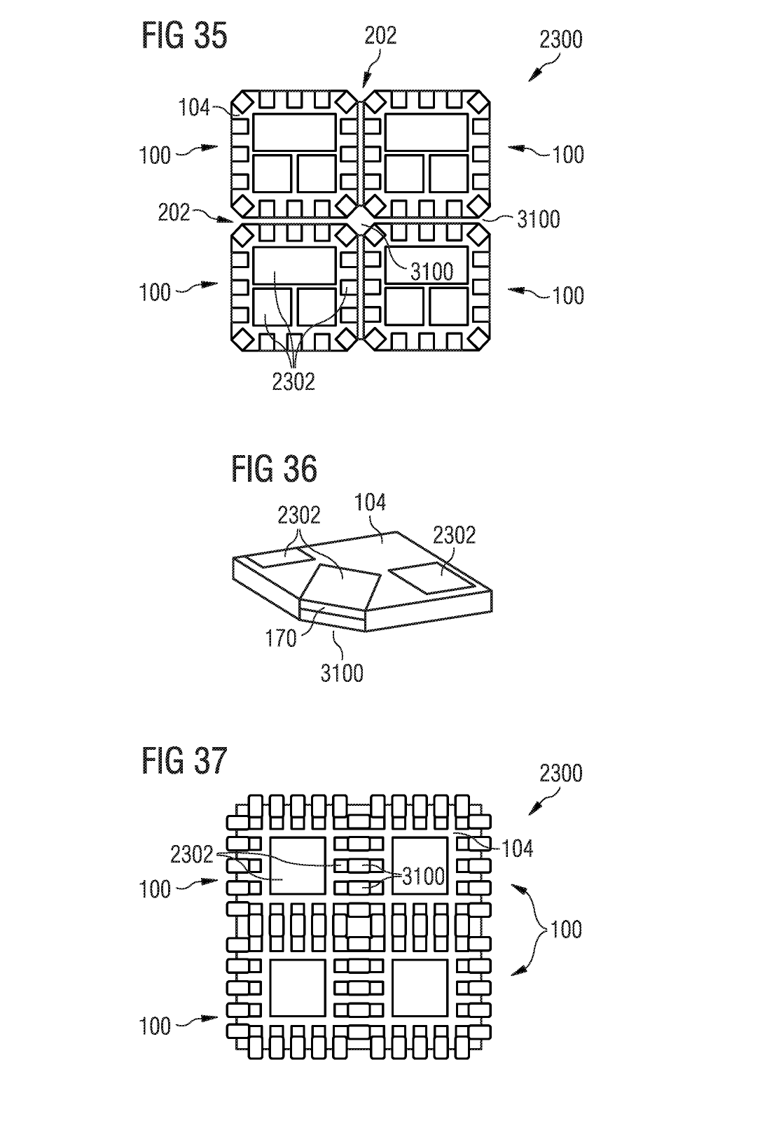

FIG. 34 illustrates a plan view of a pre-form 2300 of multiple packages 100 with routed slots 3100 (having however a rounded rectangular shape in the plan view of FIG. 34) used as a basis for packages 100 according to an exemplary embodiment. The routed slots 3100 may be routed on the corners of the pre-form 3100 after patterning and before final finishing. FIG. 35 illustrates a corresponding plan view of the pre-form 2300 of multiple packages 100 after singularization. Again, the packages 100 have been encapsulated in a laminate-type encapsulant 104. During singularization, cutting along cutting lines 202 and hence along the routed slots 3100 has been carried out. FIG. 36 illustrates a three-dimensional view of a detail of a pad 2302 embedded in encapsulant 104 and being provided with a routed slot 3100 in a corner. The geometry according to FIG. 36 can be denoted as a twisted corner pad with 45° angle resulting from the shape of the slots 3100 according to FIG. 34 to FIG. 36. Inspection is hence carried out on a respective corner of the packages 100.

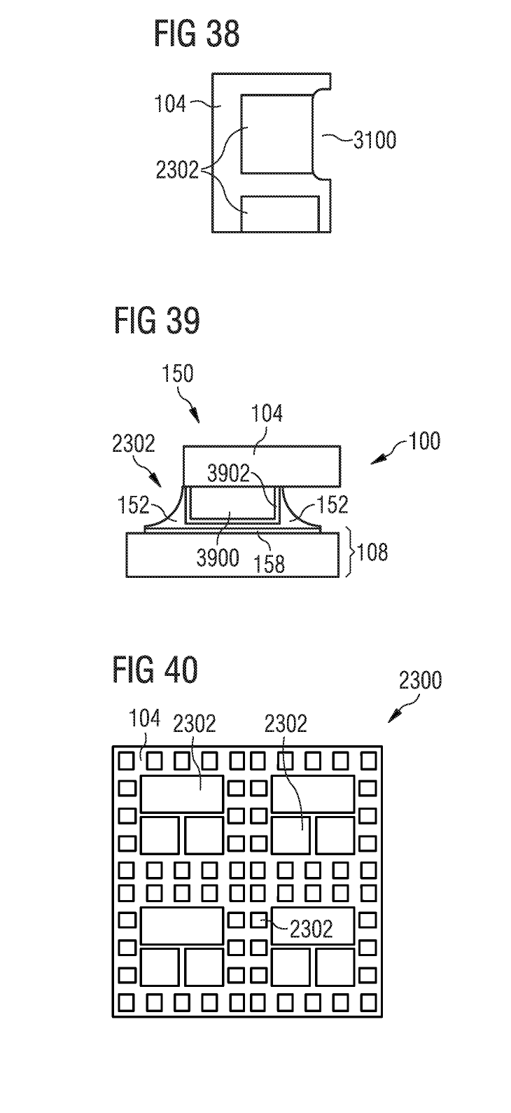

FIG. 37 illustrates a plan view of a pre-form 2300 of multiple packages 100 before singularization according to an exemplary embodiment. The embodiment according to FIG. 37 relates to an embedded power land grid delay (LGA). Slots 3100 (with rounded rectangular shape) are routed before a final finish. This is accomplished at a pin area so that a package edge corresponds to a pin edge. This embodiment results in a proper visibility of sidewall wetting after board assembly. FIG. 38 illustrates a detail of FIG. 37. FIG. 39 illustrates a cross-sectional view of a portion of FIG. 37 according to an exemplary embodiment. The cross-sectional view of FIG. 39 also shows that the pad 2302 can be formed by a metallic core 3900 (for instance a chip carrier such as a leadframe made of copper) covered by a plating 3902 which is specifically made of highly solder-wettable material (such as gold).

In particular in a scenario in which a copper leadframe or a thick copper plating is used on a pad or bottom side of the package 100, a half cut with dicing before final finishing can be used to open copper material from the sides.

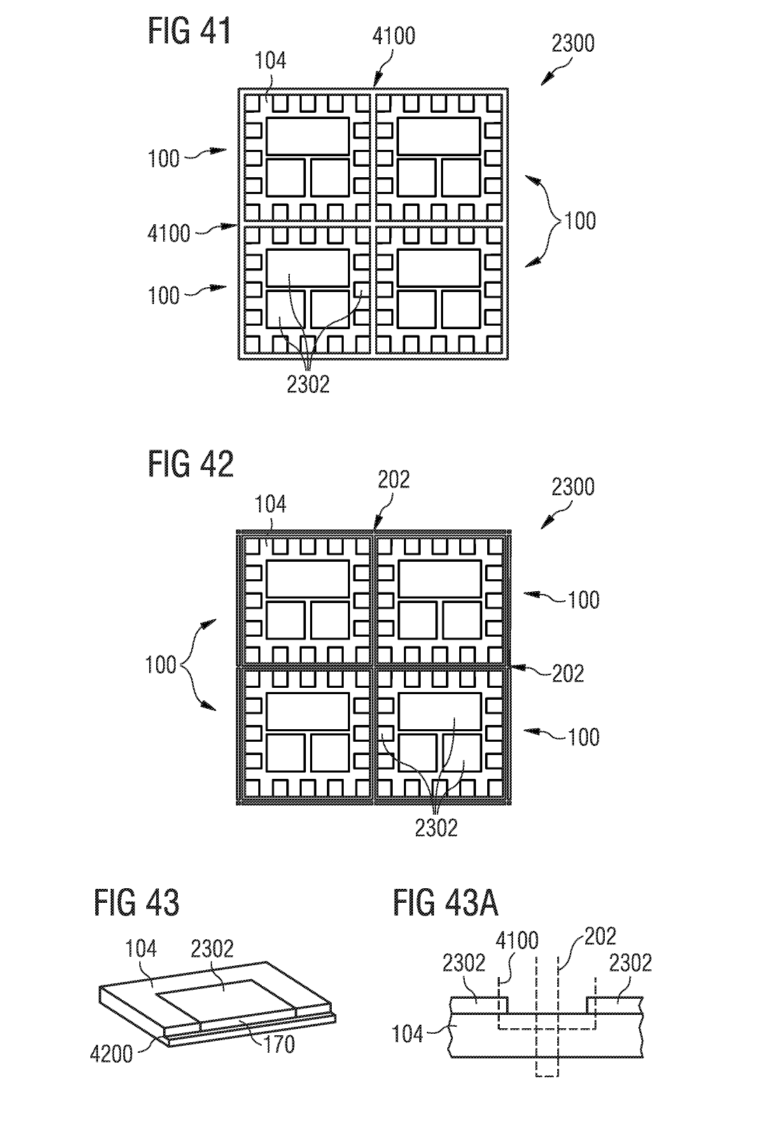

FIG. 40 illustrates a plan view of a pre-form 2300 of multiple packages 100 before singularization according to an exemplary embodiment. FIG. 41 illustrates a plan view of the pre-form 2300 after having carried out a half cut through the leadframe before final finishing (see cutting lines 4100). FIG. 42 illustrates a plan view of the pre-form 2300 after having carried out a final cut through the laminate with a thinner blade (see cutting lines 202), to thereby obtain separate packages 100. FIG. 43 illustrates a three-dimensional view of a portion of a package 100 manufactured according to FIG. 40 to FIG. 42 so as to be provided with a stepped edge 4200 according to an exemplary embodiment. FIG. 43A furthermore illustrates the two mentioned cutting procedures.

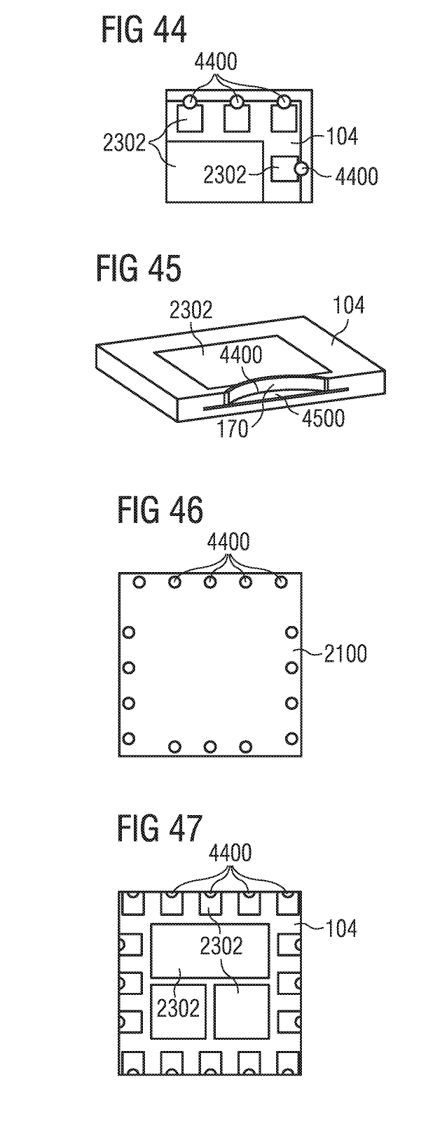

According to yet another exemplary embodiment, a large microvia may be formed on the edge of a pad 2302 before copper plating (compare FIG. 44 to FIG. 48) or before final finishing (see FIG. 49 to FIG. 53).

The embodiment according to FIG. 44 to FIG. 48 is based on the formation of blind vias and slots before structuring.

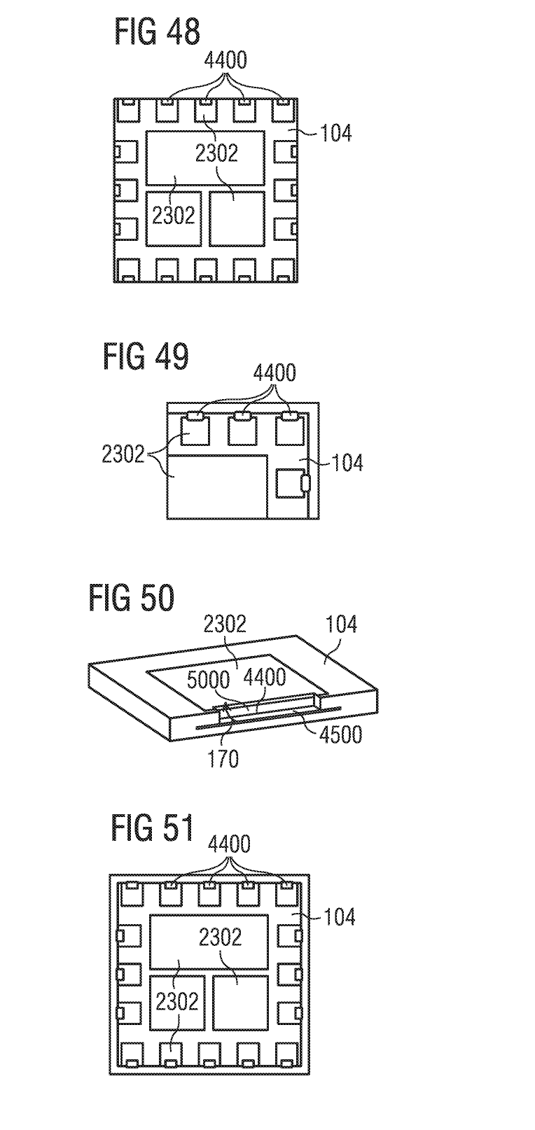

FIG. 44 illustrates a plan view of a detail of a pre-form of a package 100 according to an exemplary embodiment. In particular, a plurality of blind via holes 4400 are drilled by laser drilling on an edge of a respective pad 2302. FIG. 45 illustrates a three-dimensional view of a part of the package 100 being provided with an electrically conductive stop layer 4500 exposed by one of the via holes 4400. When a laser drill procedure reaches the stop layer 4500 from an upper side, the drilling procedure is terminated (for instance by depth control). FIG. 46 illustrates a plan view of a metallic sheet 2100 with vias 4400 as a basis of a package 100 according to the described exemplary embodiment. FIG. 47 illustrates a plan view of a package 100 after lamination and pad formation as well as singularization according to the described embodiment. By singularization from a pre-form 2300 of multiple packages 100 by cutting along a cutting line which separates the via holes 4400 in the middle, the package 100 according to FIG. 47 is obtained. As can be taken from FIG. 44 to FIG. 47, the via holes 4400 can have a circular cross section. FIG. 48 illustrates a plan view of a package 100 according to another exemplary embodiment which differs from the embodiment of FIG. 47 by the fact that the via holes 4400 according to FIG. 48 have a rounded rectangular cross section rather than a circular cross section.

In the embodiments according to FIG. 44 to FIG. 48, the via holes 4400 can be drilled at the edge of the pads 2302 (for instance partly on a dicing street). Plating can be done during formation of normal micro via holes. The via holes 4400 are then opened (for instance by dicing during panel separation) to provide for a lead tip inspection capability at a lateral or side surface of the packages 100 (see solder flow path 170 in FIG. 45).

The embodiment according to FIG. 49 to FIG. 53 is based on the formation of blind vias and slots after structuring.

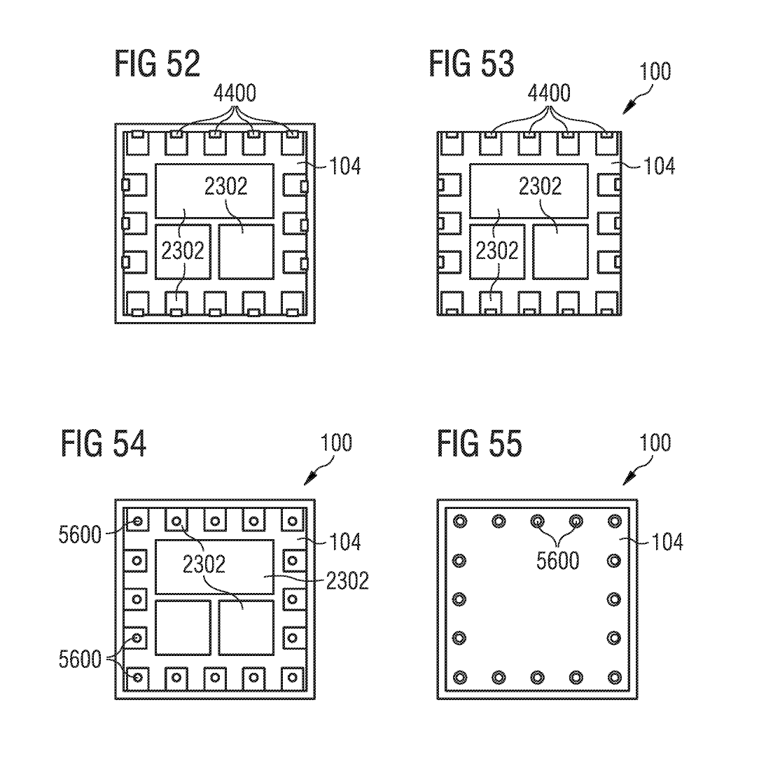

FIG. 49 illustrates a plan view of a detail of a pre-form of a package 100 according to an exemplary embodiment. In particular, a plurality of blind via holes 4400 with rounded rectangular shape are drilled by laser drilling on an edge of a respective pad 2302. FIG. 50 illustrates a three-dimensional view of a part of the package 100 being provided with an electrically conductive stop layer 4500 exposed by one of the via holes 4400. When a laser drill procedure reaches the stop layer 4500 from an upper side, the drilling procedure is terminated (for instance by depth control). Thus, the pad edge is opened before final finishing. FIG. 51 illustrates a plan view of a pre-form of a package 100 after lamination and pad formation according to an exemplary embodiment. FIG. 52 illustrates a plan view of the pre-form according to FIG. 51 after laser cleaning and surface finishing. FIG. 53 illustrates a plan view of package 100 after dicing or singularization.

In the embodiment according to FIG. 49 to FIG. 53, the substantially vertical solder flow path 170 from stop layer 4500 to pad 2302 is interrupted by a non-wettable gap 5000 of material of the laminate-type encapsulant 104. However, this gap 5000 is sufficiently narrow to allow solder material 152 to bridge the gap 5000 upon soldering.

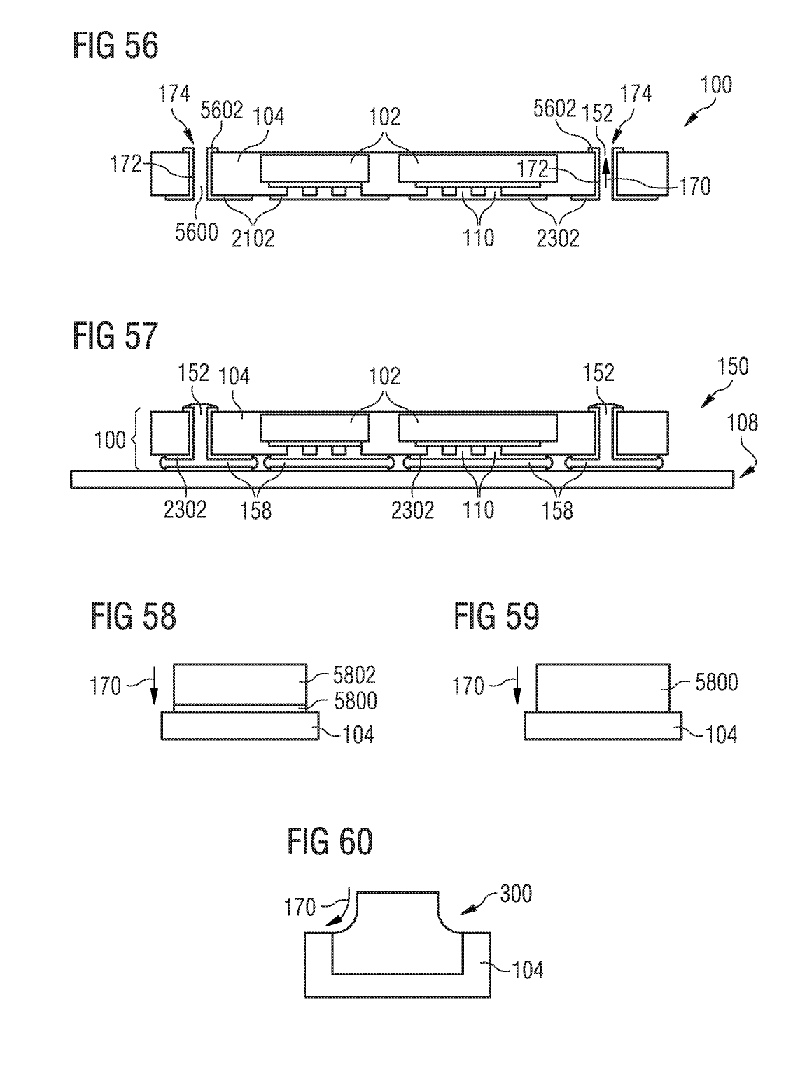

FIG. 54 illustrates a bottom side and FIG. 55 illustrates a top side of a package 100 according to an exemplary embodiment. Pads 2302 on the bottom side of the package 100 surround through holes 5600 which extend from the bottom side to the top side and are laterally delimited by a solder-wettable structure 172 (for instance plated gold). Pads 2302 are denoted in other embodiments as solderable electric contacts 106 (these terms can hence be exchanged in all embodiments). FIG. 56 illustrates a cross-sectional view of the package 100 according to FIG. 54 and FIG. 55 according to an exemplary embodiment before soldering. In the described embodiment, the solder flow path 170 is defined by the plated through-holes 5600 and the solder-wettable structure 172 extending through the package 100.

FIG. 57 illustrates a cross-sectional view of an arrangement 150 composed of the package 100 according to FIG. 54 to FIG. 56 according to an exemplary embodiment after soldering and composed of a mounting base 108 such as a printed circuit board. As can be taken from FIG. 57, by establishing a solder connection between pads 2302 of the package 100 and the solder pads 158 of the mounting base 108 by solder material 152, a part of the solder material 152 is vertically sucked and consequently flows through the plated through holes 5600 to an upper main surface of the package 100 which forms the optically inspectable surface 174 in this embodiment. This flow is triggered by the wettable property of the plating of the through holes 5600.

To obtain the embodiment according to FIG. 54 to FIG. 57, the through holes 5600 are drilled on the pads 2302. Small lands 5602 may be formed on the top side to improve accuracy of the visual inspectability of the solder connection. After the solder material 152 has raised through the wettably plated through hole 5600 up to the lands 5602, solder material 152 may be inspected on the top side of the arrangement 150, as shown in FIG. 57. An inner diameter of the through holes 5600 may be for example in a range between 0.3 mm and 2 mm, for example 0.5 mm. The individual through holes 5600 may be manufactured on the pad areas before copper plating.

A further option to create a wettable sidewall of the package terminals is to create a thick copper layer (for example at least 100 μm) as the outermost layer of the package. One way is using a thick copper base layer or a half etched leadframe, processing the layout by etching only or by processing the layout in a thin copper layer and plating copper afterwards to create a copper layer of preferably at least 100 μm thickness. The peripheral pads where the solder joint inspection is required should be located with a distance of 100 μm or less to the package edge. Afterwards it is possible to carry out a precision singulation procedure (for example etching, routing, dicing) from bottom side to release the copper sidewall of the component pads. In case of a half etched leadframe it is possible to release even the whole leadframe thickness which will lead to a higher lead tip inspection structure. Afterwards the components may run through a plating process to create the final solderable finish and the singulation process. Such and similar embodiments will be described in the following referring to FIG. 58 to FIG. 61.

FIG. 58 to FIG. 60 illustrate cross sectional view of portions of a respective package 100 according to exemplary embodiments.

In order to obtain the structure according to FIG. 58, a copper foil 5800 may be laminated on a laminate-type encapsulant 104. Subsequently, a copper plating structure 5802 may be formed on the copper foil 5800. Thereafter, the copper plating structure 5802 and the copper foil 5800 may be patterned.

In order to obtain the structure according to FIG. 59, a thick copper foil 5800 may be laminated on a laminate type encapsulant 104 and may be patterned.

In order to obtain the structure according to FIG. 60, a half-etched leadframe as chip carrier 300 may be already patterned during chip carrier processing.

Any of the structures shown in FIG. 58, FIG. 59 or FIG. 60 may be used to create a thick copper structure with a lateral surface which may serve as a solder flow path 170 or part thereof, as described above.

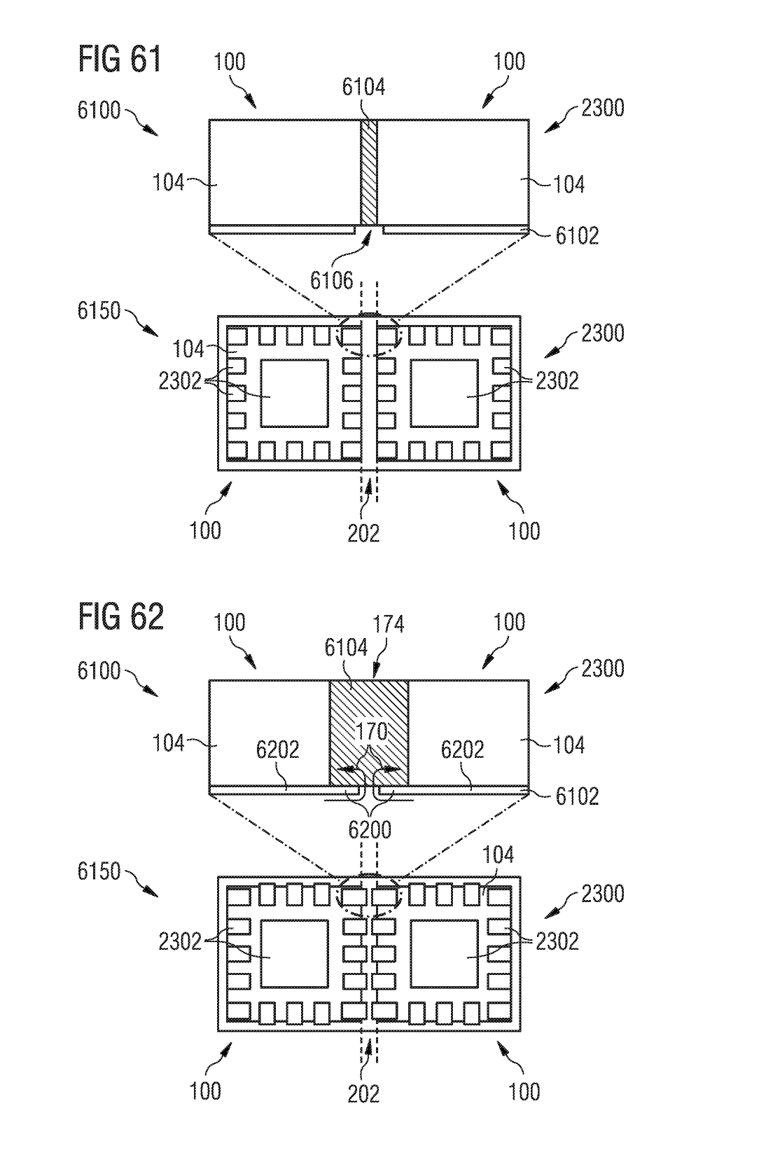

FIG. 61 illustrates a cross-sectional view 6100 of a detail of a pre-form 2300 and a plan view 6150 of the pre-form 2300 of multiple packages 100 during singularization according to an exemplary embodiment.

A structured copper layer 6102 is located at a lower main surface of the pre-form 2300. Reference numeral 6104 indicates a position where laminate material is to be removed between the two packages 100. A first separation procedure has already been accomplished at the position indicated with reference numeral 6106. To obtain the pre-form 2300, the following process flow may be carried out: copper structuring, precision singulation to release a copper sidewall, plating, and singulation of the packages 100.

Referring to FIG. 58 to FIG. 61, it can therefore be summarized that one option to create a wettable sidewall of a solderable electric contact of package 100 is to create a sufficiently thick copper layer at the outermost layer of the package 100.

Another option to create a solderable sidewall feature is to use the following process order: The first procedure again is precision separation (such as routing, dicing, laser cutting or combinations) from the top side, and stopping on top of the final copper layer which is used for bottom side structuring. Afterwards, the singulated packages may run through a single component plating process to create the final solderable surface finish. This will be described in the following in further detail:

FIG. 62 illustrates a cross-sectional view 6100 of a detail of a pre-form 2300 and a plan view 6150 of the pre-form 2300 of multiple packages 100 during singularization according to an exemplary embodiment. According to FIG. 62, the solder flow path 170 is defined by a wettable structure 6202 with a free edge 6200 configured so that solder material 152 flows around the edge 6200 towards the optically inspectable surface 174 upon soldering.

In order to manufacture the pre-form 2300 shown in FIG. 62 for forming a solderable sidewall feature, precision separation is carried out from the top side, stopping on top of the final copper layer used for bottom side structuring. Afterwards, the singulated packages 100 may run through a single component electroless plating process to create a final solderable surface finish.

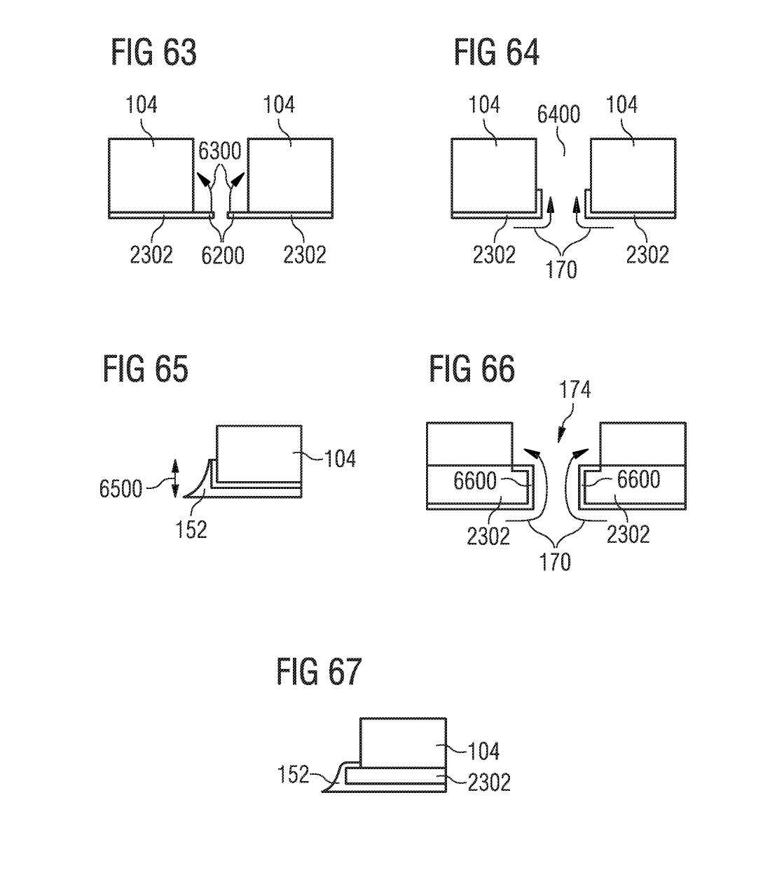

FIG. 63 and FIG. 64 illustrate a portion of a package 100 according to an exemplary embodiment in different stages during processing. As an alternative to FIG. 62, it is possible to bend (see reference numeral 6300 in FIG. 63) free edge 6200 upwardly to form an L-shaped pad 2302 (see FIG. 64) to thereby simplify flow of solder material 152 along the solder flow path 170 into an optically inspectable gap 6400 within the encapsulant 104. Furthermore, this may create a higher solderable sidewall. FIG. 65 illustrates a detail of the package 100 according to FIG. 64 after soldering showing that the bent pad 2302 according to FIG. 64 results in a larger solder fillet, and in a higher and more pronounced meniscus 6500 of solder material 152.

FIG. 66 illustrates a detail of a package 100 according to an exemplary embodiment. With the thick pad 2302 plated with a solder-wettable plating 6600 as final finish, reliable flow of solder material 152 up to an optically inspectable surface 174 can be further promoted as well.

FIG. 67 illustrates a detail of the package 100 according to FIG. 63 after soldering. According to FIG. 67, the climbed solder material 152 also covers a top surface of the pad 2302.

A simple way to create a side-wettable pad is to place the respective component pads or terminations with a distance of for example 100 μm or less to the package edge. Such an embodiment will be explained in the following.

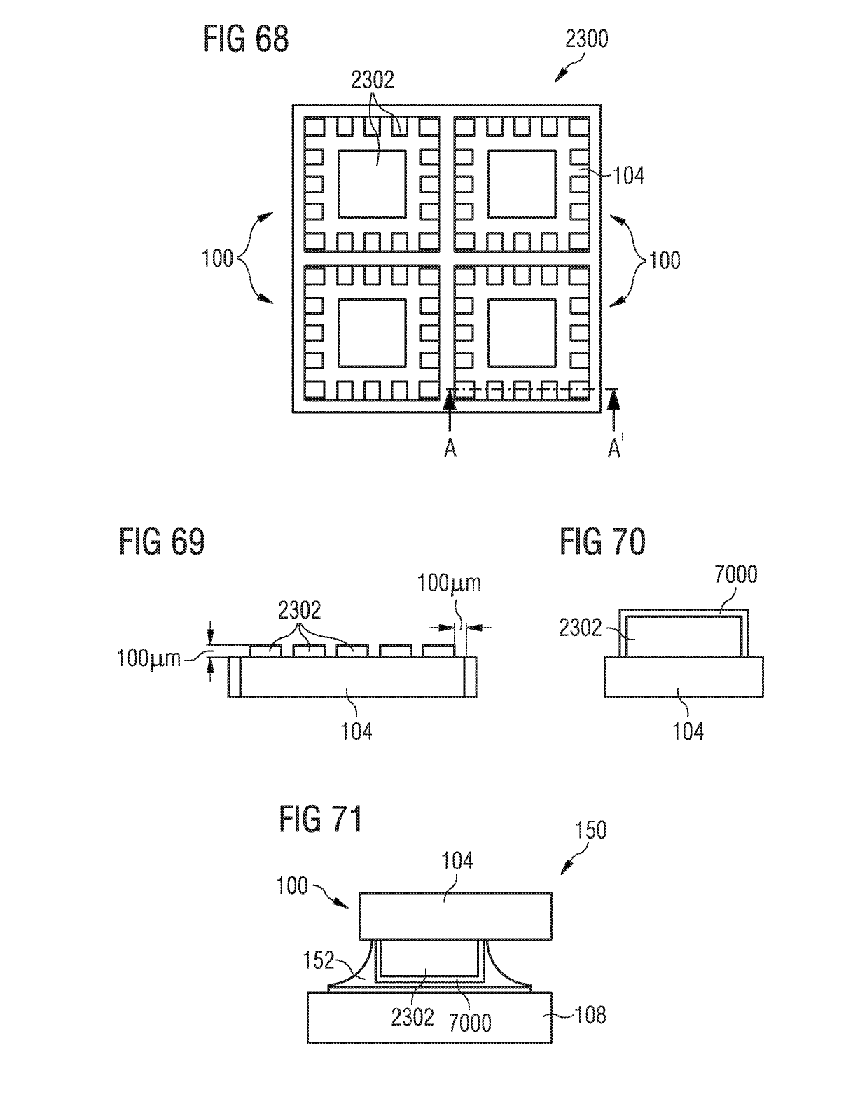

FIG. 68 illustrates a plan view of a pre-form 2300 (shown as a 2×2 panel) of multiple packages 100 according to an exemplary embodiment. FIG. 69 illustrates a cross-sectional view of a portion of the pre-form 2300 according to FIG. 68 along a line A-A′. During the processing of the final solderable finish, all exposed copper structures may be plated with a plating layer 7000, as shown in FIG. 70 which illustrates a detail of FIG. 69.

FIG. 71 illustrates a cross-sectional view of a portion of an arrangement 150 according to an exemplary embodiment. The structures shown in FIG. 68 to FIG. 70 are integrated in FIG. 71.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising
an electronic chip;
a laminate type encapsulant in and/or on which the electronic chip is mounted;
a solderable electric contact on a solder surface of the package;
a solder flow path on and/or in the package which is configured so that, upon soldering the electric contact with a mounting base, part of solder material flows along the solder flow path towards a surface of the package at which the solder material is optically inspectable after completion of the solder connection between the mounting base and the electric contact.

2. The package according to claim 1, wherein the solder flow path is at least partially defined by a solder-wettable structure on the optically inspectable surface on the encapsulant.

3. The package according to claim 1, wherein the solder flow path is at least partially defined by a surface plating with solder-wettable material.

4. The package according to claim 1, wherein the solder flow path comprises a cavity configured so that solder material flows into the cavity upon soldering.

5. The package according to claim 1, wherein the solder flow path is defined at least partially by a chip carrier on which the electronic chip is mounted, in particular a leadframe.

6. The package according to claim 1, wherein the solder flow path is located at least partially on a sidewall of the package.

7. The package according to claim 1, wherein the solder flow path is at least partially defined by a portion of a vertical through-connection exposed on a lateral surface of the package.

8. The package according to claim 1, wherein the solder flow path is located at least partially on a top surface of the package.

9. The package according to claim 1, wherein the solder flow path is at least partially defined by a hole in the package.

10. The package according to claim 1, wherein the solder flow path is at least partially defined by a through-hole, in particular a plated through-hole, extending through the package.

11. The package according to claim 1, wherein the solder flow path is continuously connected with the solderable electric contact by solderable material.

12. The package according to claim 1, wherein the solder flow path and the solderable electric contact are separated from one another by a non-wettable gap which is sufficiently narrow to allow solder material to bridge the gap upon soldering.

13. The package according to claim 1, wherein at least part of the solder flow path is defined by a wettable structure with a free edge configured so that solder material flows around the edge towards the optically inspectable surface upon soldering.

14. The package according to claim 1, wherein the solderable electric contact has a surface area of less than 1 mm², in particular of less than 0.25 mm².

15. The package according to claim 1, wherein the solder flow path is at least partially defined by material selected from the group consisting of silver, gold, nickel, palladium, platinum, nickel-phosphor, organic surface protection, and tin.

16. The package according to claim 1, wherein the electronic chip is a semiconductor chip, in particular one of the group consisting of an electronic chip manufactured in silicon carbide technology, an electronic chip manufactured in gallium nitride technology, an electronic chip manufactured in silicon germanium technology, and an electronic chip manufactured in silicon technology.

17. The package according to claim 1, configured as embedding package.

18. A package, comprising
an electronic chip;
an encapsulant encapsulating at least part of the electronic chip;
a solderable electric contact on a solder surface of the package;
a solder-wettable structure on the encapsulant and arranged so that, upon soldering the electric contact, part of solder material flows onto the solder-wettable structure;
wherein at least a portion of the solder-wettable structure is located at a surface of the package which is visually inspectable after completion of the solder connection of the electric contact.

19. The package according to claim 18, wherein the solderable electric contact is located at a surface of the package which is not visually inspectable after completion of the solder connection of the package with a mounting base.

20. An arrangement, wherein the arrangement comprises:
a package according to claim 1;
an optical inspection device arranged for optically inspecting solder material on the optically inspectable surface of the package.

21. The arrangement according to claim 20, further comprising a mounting base having a solder contact which is connected to the electric contact at the solder surface of the package by soldering.

22. The arrangement according to claim 20, further comprising solder material on an optically inspectable surface of the package.

23. A method of inspecting a solder connection between a package and a mounting base, wherein the method comprises:
providing the package with an electronic chip mounted on and/or in a laminate type encapsulant and with a solderable electric contact on a solder surface of the package at which the package is to be connected with the mounting base by soldering;
forming a solder connection between the solderable electric contact on the solder surface of the package and the mounting base in such a way that part of solder material flows from the solder surface to an optically accessible surface of the package connected with the mounting base;
optically inspecting the flown solder material on the optically accessible surface of the package.

24. The method according to claim 23, wherein the solder flow path is formed at least partially by singularizing a pre-form of multiple packages into individual packages, in particular by singularizing along a vertical through-connection.

25. The method according to claim 23, wherein the solder flow path is formed in a pre-form of multiple packages before singularizing the pre-form into multiple individual packages.

26. The method according to claim 23, wherein the solder flow path is at least partially formed by at least one of the group consisting of drilling, laser processing, milling, and routing.

27. The method according to claim 23, wherein forming the solder flow path is performed by removing material of a pre-form of multiple packages before singularization, in particular by forming the solder flow path for multiple packages simultaneously by forming a single recess in the pre-form.

28. A use of solder material which has flown, during soldering, from a visually non-inspectable surface of an embedded package to a visually inspectable surface of the package for characterizing the soldering by an optical inspection of the flown solder material.

29. The use according to claim 28, wherein a package according to claim 1 or an arrangement according to claim 20 is used.
